(19) United States
(12) Patent Application Publication
(10) Pub. No.: US 2026/0237347 A1
(43) Pub. Date: Aug. 13, 2026

(54) DISPLAY DEVICE AND ELECTRONIC DEVICE INCLUDING THE SAME

(71) Applicant: Samsung Display Co., LTD., Yongin-si (KR)

(72) Inventors: Sun Hwa LEE, Yongin-si (KR); Ji Sun KIM, Yongin-si (KR); Kyung Hoon CHUNG, Yongin-si (KR); Ji Hoon YANG, Yongin-si (KR); Min Jae JEONG, Yongin-si (KR)

(21) Appl. No.: 19/383,974

(22) Filed: Nov. 10, 2025

(30) Foreign Application Priority Data
Feb. 13, 2025 (KR) 10-2025-0018652

(51) Int. Cl. G09G 3/3233; H10K 59/131

(52) U.S. Cl. CPC G09G 3/3233; H10K 59/131; G09G 2300/0426; G09G 2300/0819; G09G 2300/0842; G09G 2300/0861; G09G 2320/0242; G09G 2330/021

(57) ABSTRACT

A display device includes a substrate including a display area in which emission areas are arranged; a circuit layer disposed on the substrate; and an element layer disposed on the circuit layer. The element layer includes light-emitting elements arranged in each of the emission areas. The circuit layer includes light-emitting pixel drivers arranged in a first direction and a second direction and transmitting a driving current to the light-emitting elements; a first power main line extending in the second direction and transmitting a first power to at least some of the light-emitting pixel drivers; and a second power main line extending in the second direction and transmitting a second power different from the first power to some others of the light-emitting pixel drivers.

### CROSS REFERENCE TO RELATED APPLICATIONS

This application claims priority to Korean Patent Application No. 10-2025-0018652, filed on Feb. 13, 2025, and all the benefits accruing therefrom under 35 U.S.C. §119, the content of which in its entirety is herein incorporated by reference.

### BACKGROUND

### Field

The disclosure relates to a display device and an electronic device including the same.

### Description of the Related Art

With the advance of information-oriented society, more and more demands are placed on display devices for displaying images in various ways. For example, display devices are employed in various electronic devices such as smartphones, digital cameras, laptop computers, navigation devices, and smart televisions.

The display device may be a flat panel display device such as a liquid crystal display device, a field emission display device and a light-emitting display device. Examples of the light-emitting display device may include an organic light-emitting display device including organic light-emitting elements, an inorganic light-emitting display device including inorganic light-emitting elements such as inorganic semiconductors, and a micro light-emitting display device including micro light-emitting elements.

The organic light-emitting display device displays an image using light-emitting elements, each including a light-emitting layer containing an organic light-emitting material. As described above, the organic light-emitting display device implements image display using a self-light-emitting element, and thus may have relatively superior performance in power consumption, response speed, luminous efficiency, luminance, and wide viewing angle compared to other display devices.

### SUMMARY

When the light-emitting elements of the display device have the same structure, the luminance of some colors may be lower than the luminance of some other colors due to the differences in the organic light-emitting materials.

In order to improve this, the light-emitting elements of some colors may include two or more light-emitting stacks. In this way, the luminance of the light-emitting element of some colors may be increased, thereby improving the display quality of the display device.

Since the light-emitting elements of some colors have a different structure from that of the light-emitting elements of some other colors, the voltage-current characteristics of the light-emitting elements of some colors may differ from those of the light-emitting elements of some other colors.

However, when all the light-emitting elements are driven by the same power regardless of the differences in the voltage-current characteristics, unnecessary power consumption may occur in the display device.

Features of the disclosure provide a display device capable of reducing power consumption while improving display quality, and an electronic device including the same.

However, features of the disclosure are not restricted to the one set forth herein. The above and other features of the disclosure will become more apparent to one of ordinary skill in the art to which the disclosure pertains by referencing the detailed description of the disclosure given below.

In an embodiment of the disclosure, there is provided a display device includes a substrate including a display area in which emission areas are arranged; a circuit layer disposed on the substrate; and an element layer disposed on the circuit layer. The element layer includes light-emitting elements arranged in each of the emission areas. The circuit layer includes light-emitting pixel drivers arranged in a first direction and a second direction which intersects the first direction and transmitting a driving current to the light-emitting elements; a first power main line extending in the second direction and transmitting a first power to at least some of the light-emitting pixel drivers; and a second power main line extending in the second direction and transmitting a second power different from the first power to some others of the light-emitting pixel drivers.

The emission areas include a first emission area, a second emission area, and a third emission area that emit light of different wavelength bands. The light-emitting pixel drivers include a first light-emitting pixel driver electrically connected to a light-emitting element of the first emission area among the light-emitting elements; a second light-emitting pixel driver electrically connected to a light-emitting element of the second emission area among the light-emitting elements; and a third light-emitting pixel driver electrically connected to a light-emitting element of the third emission area among the light-emitting elements. The first power main line is electrically connected to the first light-emitting pixel driver and the second light-emitting pixel driver. The second power main line is electrically connected to the third light-emitting pixel driver.

Each of the light-emitting pixel drivers includes a first transistor generating the driving current; a first capacitor electrically connected to a gate electrode of the first transistor; a second transistor electrically connected between a data line transmitting a data signal and a first electrode of the first transistor; a third transistor electrically connected between the gate electrode of the first transistor and a second electrode of the first transistor; a fourth transistor electrically connected between a gate initialization voltage line transmitting a gate initialization voltage and the gate electrode of the first transistor; a fifth transistor electrically connected to the first electrode of the first transistor; and a sixth transistor electrically connected between the second electrode of the first transistor and an output node. The output node is electrically connected to one of the light-emitting elements. The fifth transistor of the first light-emitting pixel driver and the fifth transistor of the second light-emitting pixel driver are electrically connected to the first power main line. The fifth transistor of the third light-emitting pixel driver is electrically connected to the second power main line.

The circuit layer further includes a first semiconductor layer disposed on the substrate; a first inter-insulating layer disposed on the first semiconductor layer; a second semiconductor layer disposed on the first inter-insulating layer; a second inter-insulating layer disposed on the second semiconductor layer; a first source-drain conductive layer disposed on the second inter-insulating layer; a first planarization layer covering the first source-drain conductive layer; a second source-drain conductive layer disposed on the first planarization layer; and a second planarization layer covering the second source-drain conductive layer. A channel portion, a first electrode and a second electrode of each of the first transistor and the fifth transistor are arranged in the first semiconductor layer. A channel portion, a first electrode and a second electrode of each of the third transistor and the fourth transistor are arranged in the second semiconductor layer.

Each of the first power main line and the second power main line is disposed in the second source-drain conductive layer. Each of the first light-emitting pixel driver and the second light-emitting pixel driver includes a first power connection electrode disposed in the first source-drain conductive layer and electrically connected to the first power main line. The first electrode of the fifth transistor of each of the first light-emitting pixel driver and the second light-emitting pixel driver is electrically connected to the first power main line through the first power connection electrode. The third light-emitting pixel driver includes a second power connection electrode disposed in the first source-drain conductive layer and electrically connected to the second power main line. The first electrode of the fifth transistor of the third light-emitting pixel driver is electrically connected to the second power main line through the second power connection electrode.

The first light-emitting pixel driver and the third light-emitting pixel driver are arranged alternately in the second direction. The second light-emitting pixel driver may be provided in plural in a manner that second light-emitting pixel drivers are arranged side by side in the second direction. The second light-emitting pixel driver is disposed between the first light-emitting pixel driver and the third light-emitting pixel driver in the first direction. The first power main line intersects the second light-emitting pixel driver. The second power main line intersects the first light-emitting pixel driver and the third light-emitting pixel driver. A first power connection electrode of the first light-emitting pixel driver and a first power connection electrode of the second light-emitting pixel driver that are next (adjacent) to each other in the first direction are connected to each other. The first power connection electrode of the first light-emitting pixel driver is electrically connected to the first power main line through the first power connection electrode of the second light-emitting pixel driver next (adjacent) to the first light-emitting pixel driver.

The circuit layer further includes a first power sub-line extending in the first direction and electrically connected to the first power main line. Each of the light-emitting pixel drivers intersects the first power sub-line. The first capacitor of each of the light-emitting pixel drivers is electrically connected to the first power sub-line.

The circuit layer further includes a first gate insulating layer covering the first semiconductor layer; a first gate conductive layer disposed on the first gate insulating layer; a second gate insulating layer covering the first gate conductive layer; and a second gate conductive layer disposed between the second gate insulating layer and the first inter-insulating layer. The gate electrode of the first transistor is disposed in the first gate conductive layer. The first power sub-line is disposed in the second gate conductive layer and electrically connected to the first power main line through the first power connection electrode. Each of the light-emitting pixel drivers further includes a capacitor electrode disposed in the second gate conductive layer and overlapping the gate electrode of the first transistor in the third direction. The capacitor electrode is a portion of the first power sub-line that overlaps the gate electrode of the first transistor. The first capacitor is formed in a region where the gate electrode of the first transistor and the capacitor electrode overlap each other in the third direction.

The circuit layer further includes a first power sub-line extending in the first direction and electrically connected to the first power main line; and a second power sub-line extending in the first direction and electrically connected to the second power main line. Between two light-emitting pixel drivers next (adjacent) to each other in the second direction, one light-emitting pixel driver intersects the first power sub-line, and a remaining (the other) light-emitting pixel driver intersects the second power sub-line.

The first capacitor of the one light-emitting pixel driver is electrically connected to the first power sub-line. The first capacitor of the remaining (the other) light-emitting pixel driver is electrically connected to the second power sub-line.

The circuit layer further includes a first gate insulating layer covering the first semiconductor layer; a first gate conductive layer disposed on the first gate insulating layer; a second gate insulating layer covering the first gate conductive layer; and a second gate conductive layer disposed between the second gate insulating layer and the first inter-insulating layer. The gate electrode of the first transistor is disposed in the first gate conductive layer. The first power sub-line and the second power sub-line are disposed in the second gate conductive layer. Each of the light-emitting pixel drivers further includes a capacitor electrode disposed in the second gate conductive layer and overlapping the gate electrode of the first transistor in the third direction. The first capacitor is formed in a region where the gate electrode of the first transistor and the capacitor electrode overlap each other. The capacitor electrode of the one light-emitting pixel driver is a part of the first power sub-line. The capacitor electrode of the remaining (the other) light-emitting pixel driver is a part of the second power sub-line.

The first capacitor of the first light-emitting pixel driver and the first capacitor of the second light-emitting pixel driver are electrically connected to the first power main line. The first capacitor of the third light-emitting pixel driver is electrically connected to the second power main line.

The circuit layer further includes a first gate insulating layer covering the first semiconductor layer; a first gate conductive layer disposed on the first gate insulating layer; a second gate insulating layer covering the first gate conductive layer; a second gate conductive layer disposed between the second gate insulating layer and the first inter-insulating layer. A third gate insulating layer covering the second semiconductor layer; and a third gate conductive layer disposed between the third gate insulating layer and the second inter-insulating layer. The gate electrode of the first transistor is disposed in the first gate conductive layer. Each of the light-emitting pixel drivers further includes a capacitor electrode disposed in an island shape in the second gate conductive layer and overlapping the gate electrode of the first transistor in the third direction. The first capacitor is formed in a region where the gate electrode of the first transistor and the capacitor electrode overlap each other. The first power sub-line and the second power sub-line are disposed in the third gate conductive layer. The first power sub-line, the capacitor electrode of the first light-emitting pixel driver, and the capacitor electrode of the second light-emitting pixel driver are electrically connected to the first power main line through the first power connection electrode. The second power sub-line and the capacitor electrode of the third light-emitting pixel driver are electrically connected to the second power main line through the second power connection electrode.

The first emission area emits light of a first wavelength band. The second emission area emits light of a second wavelength band lower than the first wavelength band. The third emission area emits light of a third wavelength band lower than the second wavelength band. Each of the light-emitting elements includes an anode electrode and a cathode electrode opposing each other in a third direction perpendicular to the first and second directions, and an organic layer disposed between the anode electrode and the cathode electrode. Each of the organic layer of the light-emitting element of the first emission area and the organic layer of the light-emitting element of the second emission area includes one light-emitting stack. The organic layer of the light-emitting element of the third emission area includes two or more light-emitting stacks, and at least one carrier generation layer disposed between the two or more light-emitting stacks. Each of the one light-emitting stack and the two or more light-emitting stacks includes a light-emitting layer in which an electron-hole pair is converted into light.

In an embodiment of the disclosure, there is provided an electronic device includes a display device displaying an image; a memory storing an application; a processor executing the application and transmitting an image data signal and an input control signal to the display device; and a power module transmitting a power to the display device. The display device includes a substrate including a display area in which emission areas are arranged; a circuit layer disposed on the substrate; and an element layer disposed on the circuit layer. The element layer includes light-emitting elements arranged in each of the emission areas. The circuit layer includes light-emitting pixel drivers arranged in a first direction and a second direction and transmitting a driving current to the light-emitting elements; a first power main line extending in the second direction and transmitting a first power to at least some of the light-emitting pixel drivers; and a second power main line extending in the second direction and transmitting a second power different from the first power to some others of the light-emitting pixel drivers. The emission areas include a first emission area, a second emission area, and a third emission area that emit light of different wavelength bands. The light-emitting pixel drivers include a first light-emitting pixel driver electrically connected to the light-emitting element of the first emission area; a second light-emitting pixel driver electrically connected to the light-emitting element of the second emission area; and a third light-emitting pixel driver electrically connected to the light-emitting element of the third emission area. The first power main line is electrically connected to the first light-emitting pixel driver and the second light-emitting pixel driver. The second power main line is electrically connected to the third light-emitting pixel driver.

Each of the light-emitting pixel drivers includes a first transistor generating the driving current; a first capacitor electrically connected to a gate electrode of the first transistor; a second transistor electrically connected between a data line transmitting a data signal and a first electrode of the first transistor; a third transistor electrically connected between the gate electrode of the first transistor and a second electrode of the first transistor; a fourth transistor electrically connected between a gate initialization voltage line transmitting a gate initialization voltage and the gate electrode of the first transistor; a fifth transistor electrically connected to the first electrode of the first transistor; and a sixth transistor electrically connected between the second electrode of the first transistor and an output node. The output node is electrically connected to one of the light-emitting elements. The circuit layer further includes a first semiconductor layer disposed on the substrate; a first inter-insulating layer disposed on the first semiconductor layer; a second semiconductor layer disposed on the first inter-insulating layer; a second inter-insulating layer disposed on the second semiconductor layer; a first source-drain conductive layer disposed on the second inter-insulating layer; a first planarization layer covering the first source-drain conductive layer; a second source-drain conductive layer disposed on the first planarization layer; and a second planarization layer covering the second source-drain conductive layer. A channel portion, a first electrode and a second electrode of each of the first transistor and the fifth transistor are arranged in the first semiconductor layer. The first power main line and the second power main line are disposed in the second source-drain conductive layer. Each of the first light-emitting pixel driver and the second light-emitting pixel driver includes a first power connection electrode disposed in the first source-drain conductive layer and electrically connected to the first power main line. The first electrode of the fifth transistor of each of the first light-emitting pixel driver and the second light-emitting pixel driver is electrically connected to the first power main line through the first power connection electrode. The third light-emitting pixel driver includes a second power connection electrode disposed in the first source-drain conductive layer and electrically connected to the second power main line. The first electrode of the fifth transistor of the third light-emitting pixel driver is electrically connected to the second power main line through the second power connection electrode.

The circuit layer further includes a first gate insulating layer covering the first semiconductor layer; a first gate conductive layer disposed on the first gate insulating layer; a second gate insulating layer covering the first gate conductive layer; a second gate conductive layer disposed between the second gate insulating layer and the first inter-insulating layer; and a first power sub-line extending in the first direction, disposed in the second gate conductive layer, and electrically connected to the first power main line through the first power connection electrode. Each of the light-emitting pixel drivers intersects the first power sub-line. The first capacitor of each of the light-emitting pixel drivers is electrically connected to the first power sub-line.

The circuit layer further includes a first gate insulating layer covering the first semiconductor layer; a first gate conductive layer disposed on the first gate insulating layer; a second gate insulating layer covering the first gate conductive layer; a second gate conductive layer disposed between the second gate insulating layer and the first inter-insulating layer; a first power sub-line extending in the first direction, disposed in the second gate conductive layer, and electrically connected to the first power main line through the first power connection electrode; and a second power sub-line extending in the first direction, disposed in the second gate conductive layer, and electrically connected to the second power main line through the second power connection electrode. Between two light-emitting pixel drivers next (adjacent) to each other in the second direction, one light-emitting pixel driver intersects the first power sub-line, and a remaining (the other) light-emitting pixel driver intersects the second power sub-line. The gate electrode of the first transistor is disposed in the first gate conductive layer. Each of the light-emitting pixel drivers further includes a capacitor electrode disposed in the second gate conductive layer, and overlapping the gate electrode of the first transistor in a third direction. The first capacitor is formed in a region where the gate electrode of the first transistor and the capacitor electrode overlap each other. The capacitor electrode of the one light-emitting pixel driver is a part of the first power sub-line. The capacitor electrode of the remaining (the other) light-emitting pixel driver is a part of the second power sub-line.

The circuit layer further includes a first power sub-line extending in the first direction and electrically connected to the first power main line; and a second power sub-line extending in the first direction and electrically connected to the second power main line. Between two light-emitting pixel drivers next (adjacent) to each other in the second direction, one light-emitting pixel driver intersects the first power sub-line, and the remaining (the other) light-emitting pixel driver intersects the second power sub-line. The first capacitor of the first light-emitting pixel driver and the first capacitor of the second light-emitting pixel driver are electrically connected to the first power main line through the first power connection electrode. The first capacitor of the third light-emitting pixel driver is electrically connected to the second power main line through the second power connection electrode.

The circuit layer further includes a first gate insulating layer covering the first semiconductor layer; a first gate conductive layer disposed on the first gate insulating layer; a second gate insulating layer covering the first gate conductive layer; a second gate conductive layer disposed between the second gate insulating layer and the first inter-insulating layer. A third gate insulating layer covering the second semiconductor layer; and a third gate conductive layer disposed between the third gate insulating layer and the second inter-insulating layer. The gate electrode of the first transistor is disposed in the first gate conductive layer. Each of the light-emitting pixel drivers further includes a capacitor electrode disposed in an island shape in the second gate conductive layer and overlapping the gate electrode of the first transistor in the third direction. The first capacitor is formed in a region where the gate electrode of the first transistor and the capacitor electrode overlap each other. The first power sub-line and the second power sub-line are disposed in the third gate conductive layer. The first power sub-line, the capacitor electrode of the first light-emitting pixel driver, and the capacitor electrode of the second light-emitting pixel driver are electrically connected to the first power main line through the first power connection electrode. The second power sub-line and the capacitor electrode of the third light-emitting pixel driver are electrically connected to the second power main line through the second power connection electrode.

The display device in an embodiment includes a circuit layer disposed on a substrate, and the circuit layer includes light-emitting pixel drivers that transmit a driving current to light-emitting elements, a first power main line for transmitting a first power to some of the light-emitting pixel drivers, and a second power main line for transmitting a second power different from the first power to some others of the light-emitting pixel drivers.

In this way, some of the light-emitting pixel drivers may generate a driving current corresponding to the first power, while some others thereof may generate a driving current corresponding to the second power.

Accordingly, the light-emitting element electrically connected to some others of the light-emitting pixel drivers may be driven by a driving current corresponding to the second power, thereby improving luminance and improving the display quality of the display device.

In addition, one of the first power and the second power may be selected according to the voltage-current characteristics of the light-emitting element, so that the power of the display device may not be unnecessarily consumed. As a result, the power consumption of the display device and the electronic device including the same may be reduced.

It should be noted that effects of the disclosure are not limited to those described above and other effects of the disclosure will be apparent to those skilled in the art from the following descriptions.

### BRIEF DESCRIPTION OF THE DRAWINGS

The above and other advantages and features of the disclosure will become more apparent by describing in detail embodiments thereof with reference to the attached drawings, in which:

FIG. 1 is a perspective view showing an embodiment of an electronic device;

FIG. 2 is an exploded perspective view of the electronic device shown in FIG. 1;

FIG. 3 is a plan view illustrating the display device of FIG. 2;

FIG. 4 is a cross-sectional view taken along line A-A' of FIG. 3;

FIG. 5 is a schematic view showing part B of FIG. 3;

FIG. 6 is a cross-sectional view taken along line C-C' of FIG. 5;

FIG. 7 is a cross-sectional view showing the first light-emitting element of FIG. 6 in detail;

FIG. 8 is a cross-sectional view showing the third light-emitting element of FIG. 6 in detail;

FIG. 9 is a block diagram showing the display device of FIG. 2;

FIG. 10 is an equivalent circuit diagram showing an embodiment of the first light-emitting pixel driver of FIG. 5;

FIG. 11 is an equivalent circuit diagram showing an embodiment of the third light-emitting pixel driver of FIG. 5;

FIG. 12 is a schematic view showing an embodiment of the circuit layer of part D of FIG. 5;

FIGS. 13 to 19 are plan views showing an embodiment of the circuit layer of part D in FIG. 5 in an embodiment of FIG. 12;

FIG. 20 is a cross-sectional view taken along line E-E' of FIG. 19;

FIG. 21 is a cross-sectional view taken along line F-F' of FIG. 19;

FIG. 22 is a schematic view showing an embodiment of the circuit layer of part D of FIG. 5;

FIGS. 23 and 24 are plan views showing an embodiment of the circuit layer of part D of FIG. 5;

FIG. 25 is a cross-sectional view taken along line G-G' of FIG. 24;

FIG. 26 is a cross-sectional view taken along line H-H' of FIG. 24;

FIG. 27 is a schematic view showing an embodiment of the circuit layer of part D of FIG. 5;

FIGS. 28, 29, 30, and 31 are schematic views showing an embodiment of the circuit layer of part D of FIG. 5;

FIG. 32 is a cross-sectional view taken along line I-I' of FIG. 31;

FIG. 33 is a cross-sectional view taken along line J-J' of FIG. 31;

FIG. 34 is a block diagram of an embodiment of an electronic device; and

FIG. 35 is schematic views of embodiments of electronic devices.

### DETAILED DESCRIPTION

The embodiments will now be described more fully hereinafter with reference to the accompanying drawings. The embodiments may, however, be provided in different forms and should not be construed as limiting. The same reference numbers indicate the same components throughout the disclosure. In the accompanying drawing figures, the thickness of layers and regions may be exaggerated for clarity.

Some of the parts which are not associated with the description may not be provided in order to describe embodiments of the disclosure.

It will also be understood that when a layer is referred to as being "on" another layer or substrate, it may be directly on the other layer or substrate, or intervening layers may also be present. In contrast, when an element is referred to as being "directly on" another element, there may be no intervening elements present.

Further, the phrase "in a plan view" means when an object portion is viewed from above, and the phrase "in a schematic cross-sectional view" means when a schematic cross-section taken by vertically cutting an object portion is viewed from the side. The terms "overlap" or "overlapped" mean that a first object may be above or below or to a side of a second object, and vice versa. Additionally, the term "overlap" may include layer, stack, face or facing, extending over, covering, or partly covering or any other suitable term as would be appreciated and understood by those of ordinary skill in the art. The expression "not overlap" may include meaning such as "apart from" or "set aside from" or "offset from" and any other suitable equivalents as would be appreciated and understood by those of ordinary skill in the art. The terms "face" and "facing" may mean that a first object may directly or indirectly oppose a second object. In a case in which a third object intervenes between a first and second object, the first and second objects may be understood as being indirectly opposed to one another, although still facing each other.

The spatially relative terms "below," "beneath," "lower," "above," "upper," or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned "below" or "beneath" another device may be placed "above" another device. Accordingly, the illustrative term "below" may include both the lower and upper positions. The device may also be oriented in other directions and thus the spatially relative terms may be interpreted differently depending on the orientations.

When an element is referred to as being "connected" or "coupled" to another element, the element may be "directly connected" or "directly coupled" to another element, or "electrically connected" or "electrically coupled" to another element with one or more intervening elements interposed therebetween. It will be further understood that when the terms "comprises," "comprising," "has," "have," "having," "includes" and/or "including" are used, they may specify the presence of stated features, integers, steps, operations, elements and/or components, but do not preclude the presence or addition of other features, integers, steps, operations, elements, components, and/or any combination thereof.

It will be understood that, although the terms "first," "second," "third," or the like may be used herein to describe various elements, these elements should not be limited by these terms. These terms are used to distinguish one element from another element or for the convenience of description and explanation thereof. For example, when "a first element" is discussed in the description, it may be termed "a second element" or "a third element," and "a second element" and "a third element" may be termed in a similar manner without departing from the teachings herein.

The terms "about" or "approximately" as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, "about" may mean within one or more standard deviations, or within ± 30%, 20%, 10%, 5% of the stated value.

In the specification and the claims, the term "and/or" is intended to include any combination of the terms "and" and "or" for the purpose of its meaning and interpretation. For example, "A and/or B" may be understood to mean "A, B, or A and B." The terms "and" and "or" may be used in the conjunctive or disjunctive sense and may be understood to be equivalent to "and/or." In the specification and the claims, the phrase "at least one of" is intended to include the meaning of "at least one selected from the group of" for the purpose of its meaning and interpretation. For example, "at least one of A and B" may be understood to mean "A, B, or A and B."

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described with reference to the accompanying drawings.

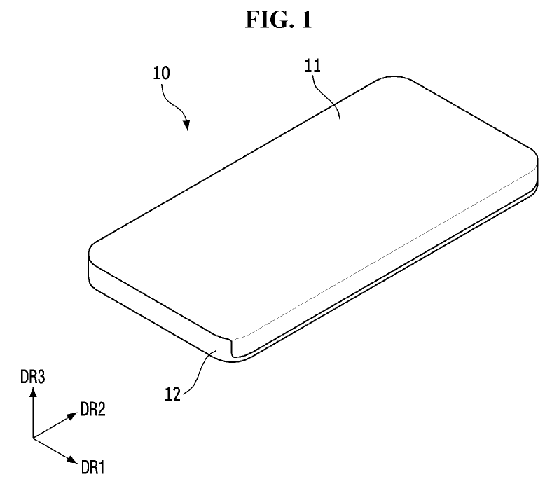

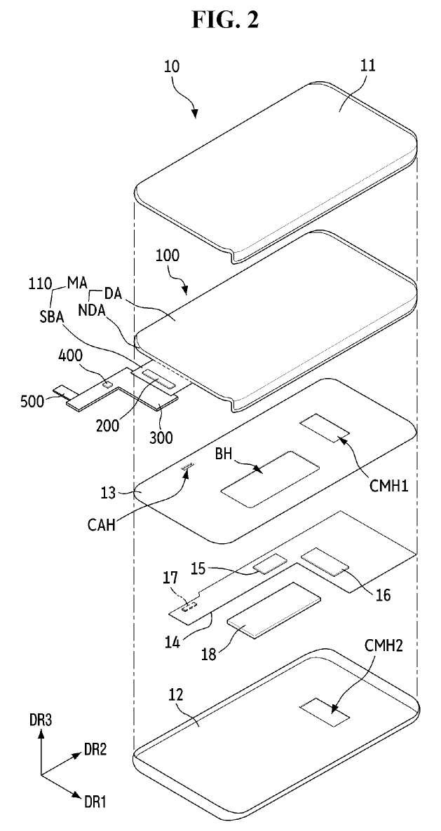

FIG. 1 is a perspective view showing an embodiment of an electronic device. FIG. 2 is an exploded perspective view of the electronic device shown in FIG. 1.

Referring to FIG. 1, an electronic device 10 in an embodiment is a device having a function of displaying an image in a display area. The electronic device 10 may provide portability. In an embodiment, the electronic device 10 may be a portable electronic device such as a mobile phone, a smartphone, a tablet personal computer (“PC”), a smart watch, a watch phone, a mobile communication terminal, an electronic notebook, an electronic book, a portable multimedia player (“PMP”), a navigation device and an ultra-mobile PC (“UMPC”), for example.

The electronic device 10 in an embodiment is not limited to a portable electronic device, and may be a large-sized device such as a television, a laptop computer, a monitor, a billboard, and an Internet-of-Things (“IoT”) device.

The electronic device 10 may have a shape close to a quadrangular shape, e.g., rectangular shape in a plan view. In an embodiment, the electronic device 10 may have a quadrangular shape, e.g., rectangular shape, in a plan view, having a short side in the first direction DR1 and a long side in the second direction DR2. A corner where the short side in the first direction DR1 and the long side in the second direction DR2 meet may be right-angled or rounded with a selected curvature. The planar shape of the electronic device 10 is not limited to the quadrangular shape, e.g., rectangular shape, and may be formed in another polygonal shape, a circular shape or an elliptical shape.

In the disclosure, a first direction DR1 may be a direction parallel to a short side of the electronic device 10 in a plan view, that is, a horizontal direction of the electronic device 10. A second direction DR2 may be a direction parallel to a long side of the electronic device 10 in a plan view, that is, a vertical direction of the electronic device 10. A third direction DR3 may be a thickness direction of the electronic device 10.

The electronic device 10 in an embodiment may include a display device 100 (refer to FIG. 2), and a cover window 11 and a lower cover 12, which are provided as a housing to protect the display device 100 (refer to FIG. 2).

Referring to FIG. 2, the electronic device 10 may further include the display device 100, a bracket 13, and a main circuit board 14, which are accommodated between the cover window 11 and the lower cover 12.

The electronic device 10 may include a display surface on which a display area DA where an image display is implemented is disposed.

The display device 100 may include the display area DA that emits light toward the display surface of the electronic device 10.

The cover window 11 may be disposed on the display device 100 to cover the top surface of the display device 100. The cover window 11 may serve to protect the top surface of the display device 100.

The cover window 11 may include a light-transmitting portion that is transparent and a light-blocking portion that is opaque.

The light-transmitting portion of the cover window 11 may overlap the display area DA of the display device 100 in the third direction DR3, and the light-blocking portion of the cover window 11 may overlap a non-display area NDA of the display device 100 in the third direction DR3.

The cover window 11 may include a top surface portion forming the top surface of the electronic device 10, a left surface portion forming the left side surface of the electronic device 10, and a right surface portion forming the right side surface of the electronic device 10. The left surface portion of the cover window 11 may extend from the left side of the top surface portion, and the right surface portion thereof may extend from the right side of the top surface portion.

Each of the top, left, and right surface portions of the cover window 11 may include the light-transmitting portion and the light-blocking portion.

The light-transmitting portion of the cover window 11 may be disposed on most of each of the top, left, and right surface portions of the cover window 11.

The light-blocking portion of the cover window 11 may be disposed at the upper edge and lower edge of the top surface portion of the cover window 11, the upper edge, left edge, and lower edge of the left surface portion of the cover window 11, and the upper edge, right edge, and lower edge of the right surface portion of the cover window 11.

The display device 100 may include a top surface portion facing the top surface portion of the cover window 11, a left surface portion facing the left surface portion of the cover window 11, and a right surface portion facing the right surface portion of the cover window 11. The left surface portion of the display device 100 may extend from the left side of the top surface portion, and the right surface portion of the display device 100 may extend from the right side of the top surface portion.

The display device 100 may include the display area DA for displaying an image.

Each of the top, left, and right surface portions of the display device 100 may include the display area DA.

The display area DA may be disposed on most of each of the top, left, and right surface portions of the display device 100.

The display device 100 may further include a display driving circuit 200, a display circuit board 300, a touch driving circuit 400, and a cable 500 extending from one side of the display circuit board 300.

The bracket 13 may be disposed under the display device 100.

The bracket 13 may include plastic, metal, or both plastic and metal. A first camera hole CMH1 into which a camera device 16 is inserted, a battery hole BH for holding a battery 18, and a cable hole CAH serving as a passage of the cable 500 connected to the display circuit board 300 may be defined in defined in the bracket 13.

The main circuit board 14 and the battery 18 may be disposed under the bracket 13. The main circuit board 14 may be a printed circuit board or a flexible printed circuit board.

A main processor 15, the camera device 16, and a main connector 17, may be disposed (e.g., mounted) on the main circuit board 14.

The camera device 16 may be disposed on both the top surface and the bottom surface of the main circuit board 14, the main processor 15 may be disposed on the top surface of the main circuit board 14, and the main connector 17 may be disposed on the bottom surface of the main circuit board 14.

The main processor 15 may control all functions of the electronic device 10.

In an embodiment, the main processor 15 may output digital video data to the display driving circuit 200 through the display circuit board 300 such that the display device 100 displays an image, for example. In addition, the main processor 15 may receive touch data including user's touch coordinates from the touch driving circuit 400, determine whether or not the user has touched or approached, and then perform an operation corresponding to the user's touch input or approach input. In an embodiment, the main processor 15 may perform an operation or execute an application indicated by an icon touched by the user, for example.

The main processor 15 may be an application processor including an integrated circuit, a central processing unit, or a system chip.

The camera device 16 may process an image frame of a still image or video obtained by an image sensor in a camera mode and output it to the main processor 15.

The cable 500 having passed through the cable hole CAH of the bracket 13 may be connected to the main connector 17. Thus, the main circuit board 14 may be electrically connected to the display circuit board 300.

The battery 18 may be spaced apart from the main circuit board 14. That is, the battery 18 may not overlap the main circuit board 14 in the third direction DR3. The battery 18 may be disposed in the battery hole BH of the bracket 13 in the third direction DR3.

In addition, the main circuit board 14 may be further equipped with a mobile communication module capable of transmitting and receiving radio signals with at least one of a base station, an external terminal, or a server in a mobile communication network. The radio signal may include various types of data according to transmission and reception of a voice signal, a video call signal, or a text/multimedia message.

The lower cover 12 may be disposed below the main circuit board 14 and the battery 18. The lower cover 12 may be fixed by being fastened to the bracket 13. The lower cover 12 may form the upper side surface, the lower side surface, and the bottom surface of the electronic device 10. The lower cover 12 may include plastic, metal, or both plastic and metal.

A second camera hole CMH2 through which the bottom surface of the camera device 16 is exposed may be defined in the lower cover 12.

However, the positions of the first camera hole CMH1 and the second camera hole CMH2 are not limited to those shown in FIG. 2.

Next, the display device 100 in embodiments will be described.

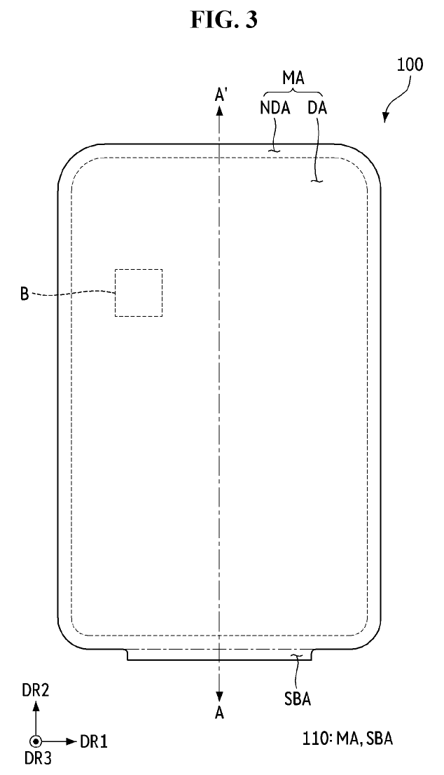

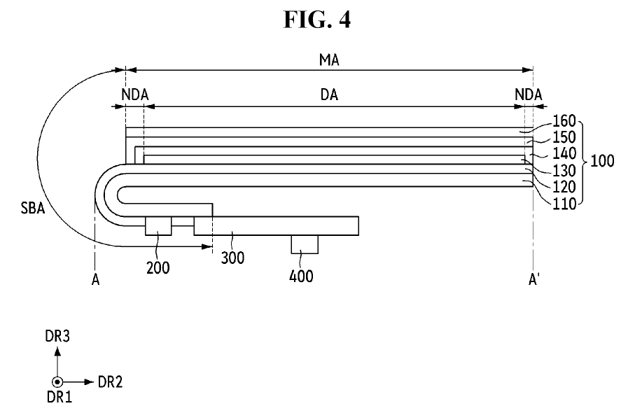

FIG. 3 is a plan view illustrating the display device of FIG. 2. FIG. 4 is a cross-sectional view taken along line A-A' of FIG. 3.

Referring to FIGS. 3 and 4, the display device 100 in an embodiment may be a light-emitting display device, such as an organic light-emitting display device using an organic light-emitting diode, a quantum dot light-emitting display device including a quantum dot light-emitting layer, an inorganic light-emitting display device including an inorganic semiconductor, and an ultra-small light-emitting display device using an ultra-small light-emitting diode (a micro or nano light-emitting diode (micro LED or nano LED)). In the following description, it is assumed that the display device 100 is an organic light-emitting display device. However, the disclosure is not limited thereto, and may be applied to a display device including an organic insulating material, an organic light-emitting material, and a metal material.

The display device 100 may be flat, but is not limited thereto. In an embodiment, the display device 100 may include a curved portion formed at left and right ends and having a constant curvature or a varying curvature, for example. In addition, the display device 100 may be flexible so that it may be curved, bent, folded, or rolled.

Referring to FIG. 3, at least one surface of the display device 100 includes a main region MA from which light for displaying an image is emitted.

The display area DA may, in a plan view, be formed in a quadrangular shape, e.g., rectangular shape having short sides in the first direction DR1 and long sides in the second direction DR2 crossing the first direction DR1. The corner where the short side in the first direction DR1 and the long side in the second direction DR2 meet may be rounded to have a selected curvature or may be right-angled. The planar shape of the display area DA is not limited to the quadrangular shape, e.g., rectangular shape, and may be formed in another polygonal shape, a circular shape or an elliptical shape.

The display area DA may be disposed in most of the main region MA. The display area DA may be disposed at the center of the main region MA.

The non-display area NDA may be disposed around the display area DA. That is, the display area DA may be surrounded by the non-display area NDA.

The display device 100 may include a substrate 110 including the main region MA and a sub-region SBA.

Referring to FIG. 4, the sub-region SBA may protrude from at least a part of one side of the main region MA in the second direction DR2.

Since a part of the sub-region SBA is transformed into a bent shape, another part of the sub-region SBA may be disposed on the rear surface of the display device 100.

In an embodiment, the display device 100 includes the substrate 110, a circuit layer 120 disposed on the substrate 110, and an element layer 130 disposed on the circuit layer 120.

The display device 100 may further include an encapsulation layer 140 disposed on the element layer 130, and a touch sensor layer 150 disposed on the encapsulation layer 140.

The display device 100 may further include a polarization layer 160 disposed on the touch sensor layer 150, in order to reduce reflection of external light.

The substrate 110 may include the main region MA corresponding to the display surface, and the sub-region SBA protruding in the second direction DR2 from at least a part of one side of the main region MA.

The main region MA may include the display area DA from which light is emitted, and the non-display area NDA disposed around the display area DA.

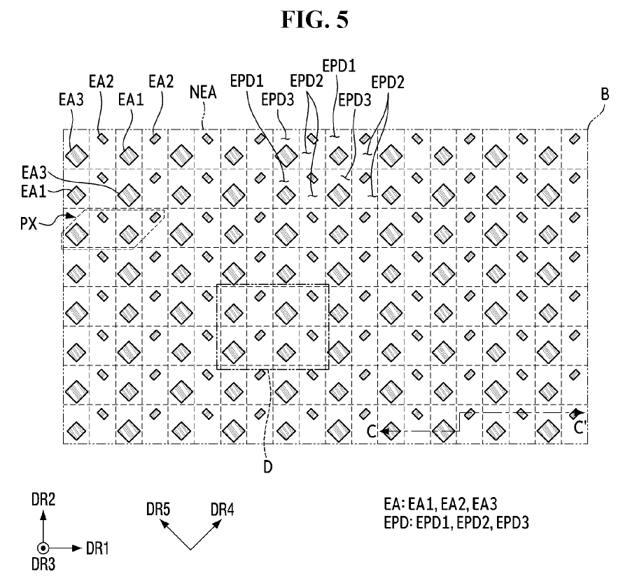

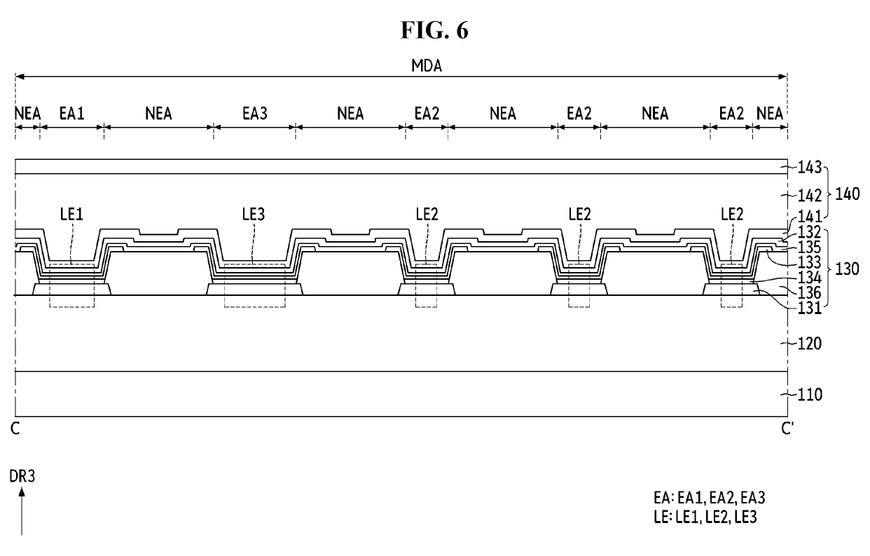

The element layer 130 may include light-emitting elements LE (refer to FIG. 6) respectively arranged in emission areas EA (refer to FIG. 5).

The circuit layer 120 may include light-emitting pixel drivers EPD (refer to FIG. 5) electrically connected to the light-emitting elements LE.

The encapsulation layer 140 may cover the element layer 130. The encapsulation layer 140 may include a structure in which two or more inorganic layers and at least one organic layer are alternately stacked.

The touch sensor layer 150 may be disposed on the encapsulation layer 140 and may correspond to the main region MA. The touch sensor layer 150 may include touch electrodes for sensing a touch of a person or an object.

The polarization layer 160 blocks external light reflected from the touch sensor layer 150, the encapsulation layer 140, the element layer 130, and the circuit layer 120, and the interfaces thereof, and this is to prevent the deterioration of visibility of an image due to external light reflection.

As a part of the sub-region SBA is transformed into a bent shape, the display driving circuit 200 disposed (e.g., mounted) in the sub-region SBA, and the display circuit board 300 connected to one side of the sub-region SBA may be disposed under the substrate 110.

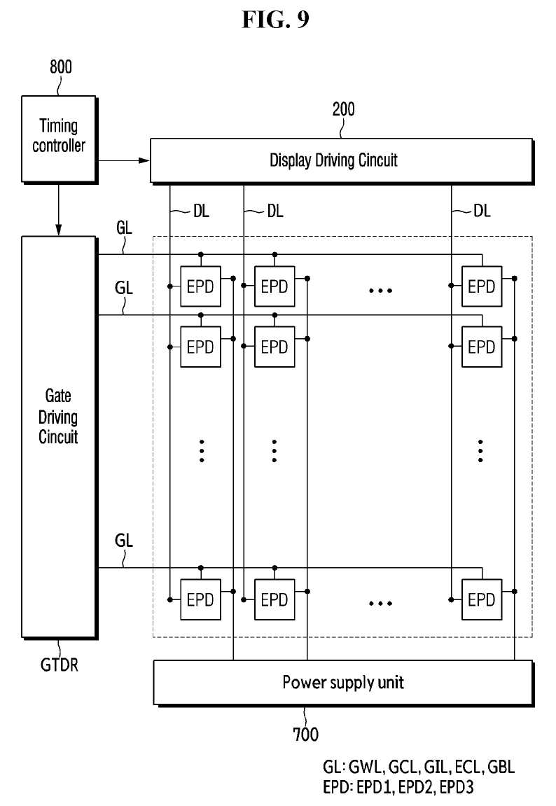

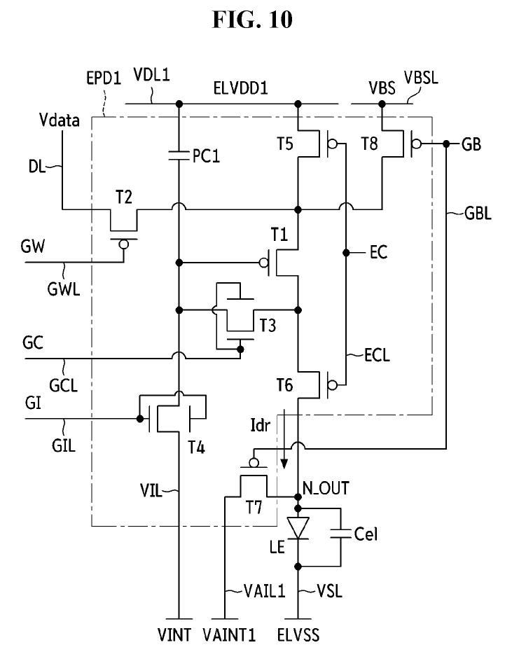

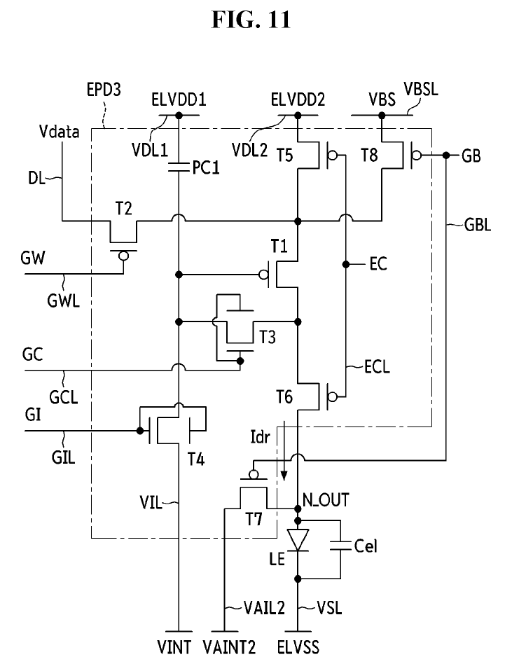

The display driving circuit 200 may be electrically connected to the data lines DL (refer to FIG. 9) of the circuit layer 120. The display driving circuit 200 may transmit the data signals Vdata (refer to FIGS. 10 and 11) of the light-emitting pixel drivers EPD (refer to FIGS. 5 and 9) to the data lines DL based on control signals and power and voltages supplied from the display circuit board 300.

The display driving circuit 200 may be provided as an integrated circuit (“IC”) and disposed (e.g., mounted) on the sub-region SBA of the display device 100 by a chip on glass (“COG”) method, a chip on plastic (“COP”) method, or an ultrasonic method. However, this is only an illustrative embodiment, and the disclosure is not limited thereto. In an embodiment, the display driving circuit 200 may be disposed (e.g., mounted) on the display circuit board 300, for example.

One end of the display circuit board 300 may be attached onto pads disposed on one edge of the sub-region SBA of the display device 100 by an anisotropic conductive film.

The display circuit board 300 may be a flexible printed circuit board (“FPCB”) which is bendable, a rigid printed circuit board (“PCB”) which maintains a flat shape, or a composite printed circuit board having both of the rigid printed circuit board and the flexible printed circuit board.

The display circuit board 300 may be connected to signal pads disposed on one side of the sub-region SBA.

The touch driving circuit 400 may be disposed (e.g., mounted) on the display circuit board 300.

The touch driving circuit 400 may be electrically connected to the touch sensor layer 150.

The touch driving circuit 400 may apply a touch driving signal to driving lines of the touch sensor layer 150, and receive a touch sensing signal from sensing lines. Further, the touch driving circuit 400 may detect charge variation amounts of capacitances based on the touch sensing signal, thereby determining whether a user has touched or approached.

The user's touch means that an object such as a pen or a user's finger is in direct contact with the top surface of the cover window disposed on the touch sensor layer 150. The user's approach means that the object such as the pen or the user's finger hovers over the top surface of the cover window.

The touch driving circuit 400 may output touch data including the user's touch coordinates to the main processor 15 (refer to FIG. 2).

FIG. 5 is a schematic view showing part B of FIG. 3. FIG. 6 is a cross-sectional view taken along line C-C' of FIG. 5.

As shown in FIG. 5, the display area DA may include the emission areas EA.

The display area DA may further include a non-emission area NEA, which is a separation area between the emission areas EA and does not emit light.

Light for image display may be emitted through the emission areas EA.

Each of the emission areas EA may be a unit area that emits light in a wavelength band corresponding to one color of two or more different colors with a luminance corresponding to an image signal.

Each of the emission areas EA may be arranged in a quadrilateral shape.

However, this is only an illustrative embodiment, and the planar shape of the emission areas EA in an embodiment is not limited to that illustrated in FIG. 5. That is, the emission areas EA may have, in a plan view, a circular shape, an elliptical shape, or a polygonal shape such as a rectangle, a square, a hexagon, or an octagon, rather than a rhombus.

The emission areas EA may include first emission areas EA1 that emit light in a first wavelength band, second emission areas EA2 that emit light in a second wavelength band lower than the first wavelength band, and third emission areas EA3 that emit light in a third wavelength band lower than the second wavelength band.

In an embodiment, the first wavelength band may be from about 600 nanometers (nm) to about 750 nm and may correspond to a red color, for example. The second wavelength band may be from about 480 nm to about 560 nm and may correspond to a green color. The third wavelength band may be from about 370 nm to about 460 nm and may correspond to a blue color.

However, this is only an illustrative embodiment, and the first wavelength band, the second wavelength band, and the third wavelength band in an embodiment are not limited thereto.

Since the emission areas EA include the first emission area EA1, the second emission area EA2, and the third emission area EA3, each of unit pixels PX may be provided by a combination of one or more first emission areas EA1, one or more second emission areas EA2, and one or more third emission areas EA3 next (adjacent) to each other among the emission areas EA.

Each of the unit pixels PX may be a unit for displaying various colors including white. That is, lights of various colors displayed by the unit pixels PX may be implemented as a combination of lights emitted from two or more emission areas EA included in each unit pixel PX.

The third emission area EA3 may have a width greater than that of the first emission area EA1, and the first emission area EA1 may have a width greater than that of the second emission area EA2. However, this is merely one of embodiments, and the width of each of the emission areas EA is not limited to that illustrated in FIG. 5.

The first emission areas EA1 and the third emission areas EA3 may be alternately arranged in the first direction DR1 and the second direction DR2.

The second emission area EA2 may be disposed parallel to each other in the first direction DR1 and the second direction DR2.

Each of the second emission areas EA2 may be next (adjacent) to the first emission area EA1 or the third emission area EA3 in diagonal directions DR4 and DR5 intersecting the first direction DR1 and the second direction DR2.

In this case, each of the unit pixels PX may include one first emission area EA1 and one third emission area EA3 next (adjacent) to each other in the first direction DR1, and two second emission areas EA2 next (adjacent) thereto in the diagonal directions DR4 and DR5. However, this is only an illustrative embodiment, and the arrangement pattern of the emission areas EA and the components of the unit pixel PX in an embodiment are not limited to the above description.

Referring to FIG. 6, in an embodiment, the element layer 130 (refer to FIG. 4) may include the light-emitting elements LE arranged in the emission areas EA.

The light-emitting elements LE may include a first light-emitting element LE1 disposed in the first emission area EA1, a second light-emitting element LE2 disposed in the second emission area EA2, and a third light-emitting element LE3 disposed in the third emission area EA3.

The first light-emitting element LE1 may emit light of the first wavelength band.

The second light-emitting element LE2 may emit light of the second wavelength band.

The third light-emitting element LE3 may emit light of the third wavelength band.

As shown in FIG. 5, in an embodiment, the circuit layer 120 (refer to FIG. 4) may include the light-emitting pixel drivers EPD arranged in the first direction DR1 and the second direction DR2.

The light-emitting pixel drivers EPD may respectively transmit a driving current Idr (refer to FIGS. 10 and 11) to the light-emitting elements LE (refer to FIG. 6) of the element layer 130 (refer to FIG. 4).

The light-emitting pixel drivers EPD may include a first light-emitting pixel driver EPD1 electrically connected to the first light-emitting element LE1 (refer to FIG. 6), a second light-emitting pixel driver EPD2 electrically connected to the second light-emitting element LE2 (refer to FIG. 6), and a third light-emitting pixel driver EPD3 electrically connected to the third light-emitting element LE3 (refer to FIG. 6).

The first light-emitting pixel driver EPD1 and the third light-emitting pixel driver EPD3 may be alternately arranged in the second direction DR2.

The second light-emitting pixel drivers EPD2 may be arranged side by side in the second direction DR2.

Each of the second light-emitting pixel drivers EPD2 may be disposed between the first light-emitting pixel driver EPD1 and the third light-emitting pixel driver EPD3 in the first direction DR1.

As shown in FIG. 6, the element layer 130 may include the light-emitting elements LE respectively disposed in the emission areas EA, respectively.

Each of the light-emitting elements LE may be an organic light-emitting diode including an organic layer of an organic light-emitting material.

In an alternative embodiment, each of the light-emitting elements LE may be one of an inorganic light-emitting element having a light-emitting layer including an inorganic semiconductor, a quantum dot light-emitting element having a quantum dot light-emitting layer, and a micro light-emitting diode.

In an embodiment, each of the light-emitting elements LE may include an anode electrode 131 and a cathode electrode 132 opposing each other, and an organic layer 133 disposed between the anode electrode 131 and the cathode electrode 132.

In another embodiment, each of the light-emitting elements LE may further include a first common layer 134 disposed between the anode electrode 131 and the organic layer 133, and a second common layer 135 disposed between the organic layer 133 and the cathode electrode 132.

The first common layer 134 may include or consist of an organic material for injecting holes.

The second common layer 135 may include or consist of an organic material for injecting electrons.

That is, the element layer 130 may include the anode electrodes 131 disposed in the emission areas EA, a pixel defining layer 136 disposed in the non-emission area NEA and covering the edges of the anode electrodes 131, the first common layers 134 disposed on the anode electrodes 131, the organic layers 133 disposed on the first common layers 134, the second common layer 135 disposed on the organic layers 133 and the pixel defining layer 136, and the cathode electrode 132 disposed on the second common layer 135.

The anode electrodes 131 may be respectively disposed in the emission areas EA, and may be respectively electrically connected to the light-emitting pixel drivers EPD (refer to FIG. 5) of the circuit layer 120. This anode electrode 131 may be also referred to as a pixel electrode.

The pixel defining layer 136 may include an organic insulating material.

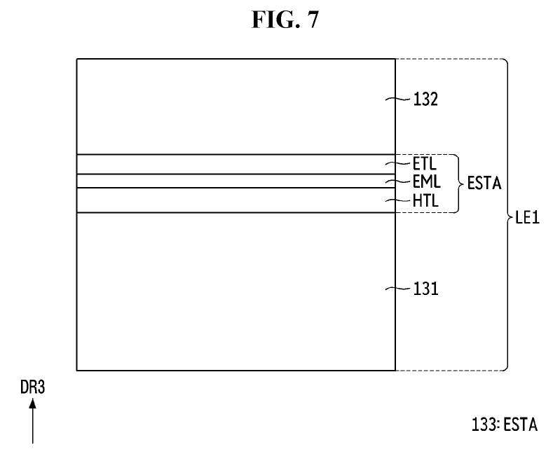

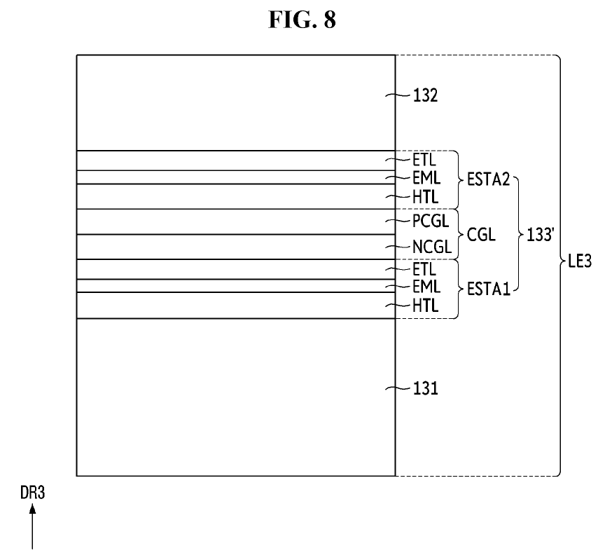

Each of the organic layers 133 may include at least one light-emitting stack ESTA (refer to FIG. 7), or light-emitting stacks ESTA1 and ESTA2 (refer to FIG. 8). Each of the at least one light-emitting stack ESTA (refer to FIG. 7), or light-emitting stacks ESTA1 and ESTA2 (refer to FIG. 8) may include a light-emitting layer EML (refer to FIGS. 7 and 8) for converting an electron-hole pair into light.

The cathode electrode 132 may be disposed in the emission areas EA and the non-emission area NEA and may be electrically connected to a third power line VSL (refer to FIGS. 10 and 11). That is, the cathode electrode 132 may be disposed entirely in the display area DA. The cathode electrode 132 may be also referred to as a common electrode.

The encapsulation layer 140 may be disposed on the circuit layer 120 and cover the element layer 130.

The encapsulation layer 140 may include a first encapsulation layer 141 disposed on the element layer 130 and including or consisting of an inorganic insulating material, a second encapsulation layer 142 covering the element layer 130 and including or consisting of an organic insulating material, and a third encapsulation layer 143 covering the second encapsulation layer 142 and including or consisting of an inorganic insulating material.

FIG. 7 is a cross-sectional view showing the first light-emitting element of FIG. 6 in detail. FIG. 8 is a cross-sectional view showing the third light-emitting element of FIG. 6 in detail.

As mentioned above, the element layer 130 of the display device 100 in an embodiment includes the first light-emitting element LE1 (refer to FIG. 6) disposed in the first emission area EA1 (refer to FIG. 6), the second light-emitting element LE2 (refer to FIG. 6) disposed in the second emission area EA2 (refer to FIG. 6), and the third light-emitting element LE3 (refer to FIG. 6) disposed in the third emission area EA3 (refer to FIG. 6).

As shown in FIGS. 7 and 8, in an embodiment, each of the first light-emitting element LE1 and the third light-emitting element LE3 may include the anode electrode 131 and the cathode electrode 132 opposing each other in the third direction DR3, and the organic layer 133, 133' disposed between the anode electrode 131 and the cathode electrode 132.

As shown in FIG. 7, the organic layer 133 of the first light-emitting element LE1 may include a single light-emitting stack ESTA.

The single light-emitting stack ESTA may include the light-emitting layer EML in which an electron-hole pair is converted into light.

The single light-emitting stack ESTA may further include a hole transport layer HTL disposed between the anode electrode 131 and the light-emitting layer EML, and an electron transport layer ETL disposed between the light-emitting layer EML and the cathode electrode 132.

In an embodiment, the second light-emitting element LE2 (refer to FIG. 6) may have a structure that is the same as or similar to that of the first light-emitting element LE1 shown in FIG. 7, and thus a redundant description thereof will be omitted.

As shown in FIG. 8, the organic layer 133' of the third light-emitting element LE3 may include two or more light-emitting stacks ESTA1 and ESTA2, and at least one carrier generation layer CGL disposed between the two or more light-emitting stacks ESTA1 and ESTA2.

Each of the two or more light-emitting stacks ESTA1 and ESTA2 may include the light-emitting layer EML in which an electron-hole pair is converted into light.

In an embodiment, the two or more light-emitting stacks ESTA1 and ESTA2 may include a first light-emitting stack ESTA1 next (adjacent) to the anode electrode 131 in the third direction DR3, and a second light-emitting stack ESTA2 next (adjacent) to the cathode electrode 132 in the third direction DR3.

In an embodiment, the organic layer 133' of the third light-emitting element LE3 may include one carrier generation layer CGL disposed between the first light-emitting stack ESTA1 and the second light-emitting stack ESTA2.

In this case, the first light-emitting stack ESTA1 may further include the hole transport layer HTL disposed between the anode electrode 131 and the light-emitting layer EML, and the electron transport layer ETL disposed between the light-emitting layer EML and the carrier generation layer CGL.

In addition, the second light-emitting stack ESTA2 may further include the hole transport layer HTL disposed between the carrier generation layer CGL and the light-emitting layer EML, and the electron transport layer ETL disposed between the light-emitting layer EML and the cathode electrode 132.

The carrier generation layer CGL may include an n-type carrier generation layer NCGL next (adjacent) to the anode electrode 131 in the third direction DR3 and a p-type carrier generation layer PCGL next (adjacent) to the cathode electrode 132 in the third direction DR3.

In an embodiment, each of the first light-emitting element LE1 and the second light-emitting element LE2 includes a single light-emitting stack ESTA (refer to FIG. 7), whereas the third light-emitting element LE3 includes two or more light-emitting stacks ESTA1 and ESTA2 (refer to FIG. 8). Accordingly, the driving voltage of the third light-emitting element LE3 may differ from the driving voltage of the first light-emitting element LE1 and the driving voltage of the second light-emitting element LE2.

FIG. 9 is a block diagram showing the display device of FIG. 2.

Referring to FIG. 9, the circuit layer 120 of the display device 100 in an embodiment may include the light-emitting pixel drivers EPD electrically connected to the light-emitting elements LE (refer to FIG. 6) disposed in the emission areas EA of the display area DA.

The light-emitting pixel drivers EPD may include a first light-emitting pixel driver EPD1 electrically connected to the first light-emitting element LE1 (refer to FIG. 6), a second light-emitting pixel driver EPD2 electrically connected to the second light-emitting element LE2 (refer to FIG. 6), and a third light-emitting pixel driver EPD3 electrically connected to the third light-emitting element LE3 (refer to FIG. 6).

In an embodiment, the circuit layer 120 may further include gate lines GL for transmitting a gate signal to the light-emitting pixel drivers EPD, and the data lines DL for transmitting the data signals Vdata (refer to FIG. 10) to the light-emitting pixel drivers EPD.

The display device 100 may further include the display driving circuit 200 that outputs the data signals Vdata (refer to FIGS. 10 and 11) for controlling the luminance of each of the light-emitting elements LE (refer to FIG. 6) to the data lines DL.

The display device 100 may further include a gate driver GTDR that outputs gate signals to the gate lines GL, a power supply unit 700 that supplies various powers and various voltages to the light-emitting pixel drivers EPD, and a timing controller 800 that controls the driving timing of each of the display driving circuit 200 and the gate driver GTDR.

The timing controller 800 receives an image signal supplied from the outside of the display device 100.

The timing controller 800 may output image data and a data control signal to the display driving circuit 200.

The timing controller 800 may generate a scan control signal for controlling the operation timing of the gate driver GTDR.

The display driving circuit 200 may convert the image data into analog data voltages and output them to the data lines DL.

The gate driver GTDR may generate gate signals in response to the scan control signal and sequentially output the gate signals to gate lines GL.

In an embodiment, the gate lines GL may include a scan write line GWL transmitting a scan write signal GW (refer to FIGS. 10 and 11), a gate control line GCL transmitting a gate control signal GC (refer to FIGS. 10 and 11), a scan initialization line GIL transmitting a scan initialization signal GI (refer to FIGS. 10 and 11), the emission control line ECL transmitting an emission control signal EC (refer to FIGS. 10 and 11), and a bias control line GBL transmitting a bias control signal GB (refer to FIGS. 10 and 11), for example.

The gate signals may have pulses that vary to a first gate level voltage or a second gate level voltage.

The power supply unit 700 may supply various power and voltages desired for driving the light-emitting pixel drivers EPD.

In an embodiment, the power supply unit 700 may supply a first power ELVDD1 (refer to FIGS. 10 and 11), a second power ELVDD2 (refer to FIG. 11), and a third power ELVSS (refer to FIGS. 10 and 11) for generating a driving signal transmitted to the light-emitting elements LE, a gate initialization voltage VINT (refer to FIGS. 10 and 11) and a bias voltage VBS (refer to FIGS. 10 and 11) for initializing the light-emitting pixel drivers EPD, a first anode initialization voltage VAINT1 (FIG. 10) for initializing the first light-emitting element LE1 (refer to FIG. 6) and the second light-emitting element LE2 (refer to FIG. 6), and a second anode initialization voltage VAINT2 (refer to FIG. 11) for initializing the third light-emitting element LE3 (refer to FIG. 6).

FIG. 10 is an equivalent circuit diagram showing an embodiment of the first light-emitting pixel driver of FIG. 5. FIG. 11 is an equivalent circuit diagram showing an embodiment of the third light-emitting pixel driver of FIG. 5.

Referring to FIGS. 10 and 11, the first light-emitting pixel driver EPD1 may be electrically connected to the first light-emitting element LE1, and the third light-emitting pixel driver EPD3 may be electrically connected to the third light-emitting element LE3.

As shown in FIGS. 10 and 11, each of the first light-emitting element LE1 and the third light-emitting element LE3 may include an intrinsic parasitic capacitance Cel.

The first light-emitting pixel driver EPD1 may be electrically connected to a first power line VDL1 for transmitting the first power ELVDD1.

Since the second light-emitting element LE2 has a structure substantially the same as or similar to that of the first light-emitting element LE1, the second light-emitting pixel driver EPD2 may have a structure substantially the same as or similar to that of the first light-emitting pixel driver EPD1. Accordingly, redundant descriptions thereof will be omitted.

In an embodiment, since the third light-emitting element LE3 includes two or more light-emitting stacks ESTA1 and ESTA2 (refer to FIG. 8), the third light-emitting pixel driver EPD3 may be electrically connected to a second power line VDL2 for transmitting the second power ELVDD2 different from the first power ELVDD1.

In an embodiment, the second power (hereinafter also referred to as a second power source) ELVDD2 may have a lower voltage level than the first power (hereinafter also referred to as a first power source) ELVDD1.

Each of the first light-emitting element LE1 and the third light-emitting element LE3 may be electrically connected to the third power line VSL for transmitting the third power ELVSS different from the first power ELVDD1 and the second power ELVDD2.

The third power (hereinafter also referred to as a third power source) ELVSS may have a lower voltage level than the first power source ELVDD1 and the second power source ELVDD2.

As shown in FIG. 10, the first light-emitting pixel driver EPD1 may be electrically connected to the first power line VDL1 transmitting the first power ELVDD1, the data line DL transmitting the data signal Vdata, a gate initialization voltage line VIL transmitting the gate initialization voltage VINT, a first anode initialization voltage line VAIL1 transmitting the first anode initialization voltage VAINT1, and a bias voltage line VBSL transmitting the bias voltage VBS.

The first light-emitting pixel driver EPD1 may be electrically connected to the scan write line GWL transmitting the scan write signal GW, the scan initialization line GIL transmitting the scan initialization signal GI, the gate control line GCL transmitting the gate control signal GC, the emission control line ECL transmitting the emission control signal EC, and the bias control line GBL transmitting the bias control signal GB.

The first light-emitting pixel driver EPD1 may include a first transistor T1 that generates a driving current Idr for driving the first light-emitting element LE1, two or more transistors (i.e., second to eighth transistors T2 to T8) electrically connected to the first transistor T1 or the first light-emitting element LE1, and at least one capacitor (i.e., a first capacitor C1).

As shown in FIGS. 10 and 11, in an embodiment, each of the first light-emitting pixel driver EPD1 and the third light-emitting pixel driver EPD3 may include the first transistor T1 generating the driving current Idr, the first capacitor C1 electrically connected to a gate electrode of the first transistor T1, the second transistor T2 electrically connected between the data line DL transmitting the data signal Vdata and a first electrode of the first transistor T1, the third transistor T3 electrically connected between the gate electrode of the first transistor T1 and a second electrode of the first transistor T1, the fourth transistor T4 electrically connected between the gate initialization voltage line VIL transmitting the gate initialization voltage VINT and the gate electrode of the first transistor T1, the fifth transistor T5 electrically connected to the first electrode of the first transistor T1, and the sixth transistor T6 electrically connected between the second electrode of the first transistor T1 and an output node N_OUT.

The output nodes N_OUT of the light-emitting pixel drivers EPD (refer to FIG. 9) of the circuit layer 120 (refer to FIG. 4) may be electrically connected to the light-emitting elements LE (refer to FIG. 6) of the element layer 130 (refer to FIG. 4), respectively.

That is, the output node N_OUT of one of the light-emitting pixel drivers EPD (refer to FIG. 9) may be electrically connected to one of the light-emitting elements LE (refer to FIG. 6).

As shown in FIG. 10, the output node N_OUT of the first light-emitting pixel driver EPD1 may be electrically connected to the first light-emitting element LE1.

As shown in FIG. 11, the output node N_OUT of the third light-emitting pixel driver EPD3 may be electrically connected to the third light-emitting element LE3.

As shown in FIG. 10, in an embodiment, the fifth transistor T5 of the first light-emitting pixel driver EPD1 may be electrically connected to the first power line VDL1 transmitting the first power ELVDD1. That is, the fifth transistor T5 of the first light-emitting pixel driver EPD1 may be electrically connected between the first power line VDL1 and the first electrode of the first transistor T1.

As shown in FIG. 11, in an embodiment, the fifth transistor T5 of the third light-emitting pixel driver EPD3 may be electrically connected to the second power line VDL2 transmitting the second power ELVDD2 that is different from the first power ELVDD1. That is, the fifth transistor T5 of the third light-emitting pixel driver EPD3 may be electrically connected between the second power line VDL2 and the first electrode of the first transistor T1.

As shown in FIGS. 10 and 11, in an embodiment, each of the first light-emitting pixel driver EPD1 and the third light-emitting pixel driver EPD3 may further include the seventh transistor T7 electrically connected to the output node N_OUT, and the eighth transistor T8 electrically connected between the bias voltage line VBSL transmitting the bias voltage VBS and the first electrode of the first transistor T1.

As shown in FIG. 10, in an embodiment, the seventh transistor T7 of the first light-emitting pixel driver EPD1 may be electrically connected to the first anode initialization voltage line VAIL1 transmitting the first anode initialization voltage VAINT1. That is, the seventh transistor T7 of the first light-emitting pixel driver EPD1 may be electrically connected between the first anode initialization voltage line VAIL1 and the anode electrode of the first light-emitting element LE1.

As shown in FIG. 11, in an embodiment, the seventh transistor T7 of the third light-emitting pixel driver EPD3 may be electrically connected between the anode electrode of the third light-emitting element LE3 and the second anode initialization voltage line VAIL2 transmitting the second anode initialization voltage VAINT2 that is different from the first anode initialization voltage VAINT1 (refer to FIG. 10).

As shown in FIG. 10, in an embodiment, the first capacitor C1 of the first light-emitting pixel driver EPD1 may be electrically connected to the first power line VDL1.

That is, the first capacitor C1 of the first light-emitting pixel driver EPD1 may be electrically connected between the first power line VDL1 and the gate electrode of the first transistor T1.

Thus, the gate electrode of the first transistor T1 may be electrically connected to the first power line VDL1 through the first capacitor C1.

The second transistor T2 may be electrically connected between the first electrode (e.g., a source electrode) of the first transistor T1 and the data line DL.

The second transistor T2 may be turned on by the scan write signal GW of the scan write line GWL.

When the second transistor T2 is turned on, the data signal Vdata of the data line DL may be transmitted to the first electrode of the first transistor T1.

The fifth transistor T5 of the first light-emitting pixel driver EPD1 may be electrically connected between the first power line VDL1 and the first electrode of the first transistor T1.

The sixth transistor T6 may be electrically connected between the second electrode (e.g., a drain electrode) of the first transistor T1 and the output node N_OUT.

The fifth transistor T5 and the sixth transistor T6 may be turned on by the emission control signal EC of the emission control line ECL.

When the data signal Vdata of the data line DL is transmitted to the gate electrode of the first transistor T1 through the second transistor T2, the voltage difference between the gate electrode of the first transistor T1 and the first electrode of the first transistor T1 may correspond to the difference voltage between the first power source ELVDD1 and the data signal Vdata.

When the voltage difference between the gate electrode of the first transistor T1 and the first electrode of the first transistor T1, i.e., a gate-source voltage difference, becomes greater than or equal to a threshold voltage, the first transistor T1 is turned on, so that the drain-source current of the first transistor T1 may be generated to have a magnitude corresponding to the data signal Vdata.

Subsequently, when the fifth transistor T5 and the sixth transistor T6 are turned on, the first transistor T1 and the first light-emitting element LE1 may be connected in series between the first power source ELVDD1 and the third power source ELVSS. Accordingly, the driving current Idr, which corresponds to the data signal Vdata and the difference voltage between the first power source ELVDD1 and the third power source ELVSS may be transmitted to the first light-emitting element LE1 through the output node N_OUT.

Accordingly, the first light-emitting element LE1 may emit light having a luminance corresponding to the data signal Vdata.

The third transistor T3 may be electrically connected between the gate electrode of the first transistor T1 and the second electrode of the first transistor T1.

The third transistor T3 may be turned on by the gate control signal GC of the gate control line GCL.

When the third transistor T3 is turned on, the voltage difference between the gate electrode of the first transistor T1 and the second electrode of the first transistor T1 may be initialized. That is, the channel portion of the first transistor T1 may be initialized.

The fourth transistor T4 may be connected between the gate electrode of the first transistor T1 and the gate initialization voltage line VIL.

The fourth transistor T4 may be turned on by the scan initialization signal GI of the scan initialization line GIL.

When the fourth transistor T4 is turned on, the potential of the gate electrode of the first transistor T1 may be initialized to the gate initialization voltage VINT.

The seventh transistor T7 of the first light-emitting pixel driver EPD1 may be electrically connected between the output node N_OUT and the first anode initialization voltage line VAIL1.

The seventh transistor T7 may be turned on by the bias control signal GB of the bias control line GBL.

When the seventh transistor T7 of the first light-emitting pixel driver EPD1 is turned on, the potential of the anode electrode of the first light-emitting element LE1 may be initialized to the first anode initialization voltage VAINT1.

The eighth transistor T8 may be electrically connected between the first electrode of the first transistor T1 and the bias voltage line VBSL.

The eighth transistor T8 may be turned on by the bias control signal GB of the bias control line GBL.

When the eighth transistor T8 is turned on, the potential of the first electrode of the first transistor T1 may be initialized to the bias voltage VBS.

In an embodiment, since the second light-emitting element LE2 has a structure substantially the same as or similar to that of the first light-emitting element LE1, the second light-emitting pixel driver EPD2 may have a structure substantially the same as or similar to that of the first light-emitting pixel driver EPD1. Accordingly, redundant descriptions thereof will be omitted.

As shown in FIG. 11, in an embodiment, the third light-emitting pixel driver EPD3 is substantially the same as or similar to the first light-emitting pixel driver EPD1 of FIG. 10 except that it is electrically connected to the third light-emitting element LE3 including two or more light-emitting stacks ESTA1 and ESTA2 (refer to FIG. 8), the fifth transistor T5 is electrically connected to the second power line VDL2 transmitting the second power ELVDD2, and the seventh transistor T7 is electrically connected to the second anode initialization voltage line VAIL2, and thus redundant description is omitted.

As the third light-emitting element LE3 includes two or more light-emitting stacks ESTA1 and ESTA2 (refer to FIG. 8), it may have a higher threshold voltage than the first light-emitting element LE1 and the second light-emitting element LE2.

Accordingly, in an embodiment, the fifth transistor T5 of the third light-emitting pixel driver EPD3 may be electrically connected to the second power line VDL2 transmitting the second power ELVDD2 that is different from the first power ELVDD1.

That is, the fifth transistor T5 of the third light-emitting pixel driver EPD3 may be electrically connected between the first electrode of the first transistor T1 and the second power line VDL2.

Accordingly, when the fifth transistor T5 and the sixth transistor T6 are turned on in the third light-emitting pixel driver EPD3, the first transistor T1 and the third light-emitting element LE3 may be connected in series between the second power source ELVDD2 and the third power source ELVSS. Accordingly, the driving current Idr corresponding to the data signal Vdata and the difference voltage between the second power source ELVDD2 and the third power source ELVSS may be transmitted to the third light-emitting element LE3 through the output node N_OUT.

As described above, in an embodiment, as the first transistor T1 of the third light-emitting pixel driver EPD3 is electrically connected to the second power line VDL2 through the fifth transistor T5, the driving current of the third light-emitting element LE3 may be generated using the second power source ELVDD2 having a lower voltage level than that of the first power source ELVDD1. Accordingly, power consumption of the display device 100 may be decreased while maintaining relatively high luminance of the third light-emitting element LE3.

In an embodiment, the first capacitor C1 of the third light-emitting pixel driver EPD3 may be electrically connected to the first power line VDL1.

That is, the first capacitor C1 of each of the light-emitting pixel drivers EPD (refer to FIG. 5) may be electrically connected to the first power line VDL1. Accordingly, since a difference in capacitance between the first capacitors C1 of the light-emitting pixel drivers EPD (refer to FIG. 5) may be prevented, it may be advantageous in uniformizing the characteristics of the light-emitting pixel drivers EPD (refer to FIG. 5).

In an embodiment, some of the first to eighth transistors T1 to T8 included in the light-emitting pixel drivers EPD (refer to FIG. 5) may be N-type MOSFETs, and others may be P-type MOSFETs.

That is, as shown in FIGS. 10 and 11, the third transistor T3 and the fourth transistor T4 may be N-type MOSFETs, and the first transistor T1, the second transistor T2, the fifth transistor T5, the sixth transistor T6, the seventh transistor T7, and the eighth transistor T8 may be P-type MOSFETs.

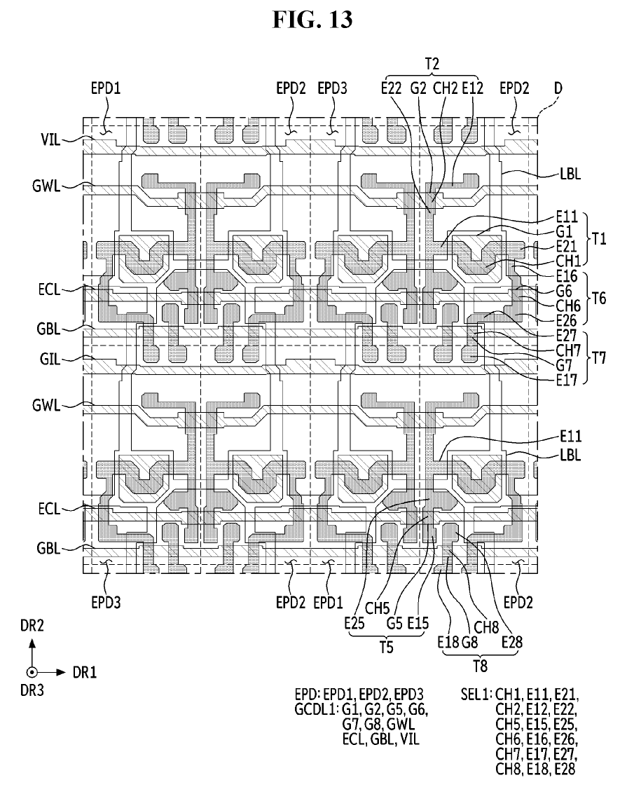

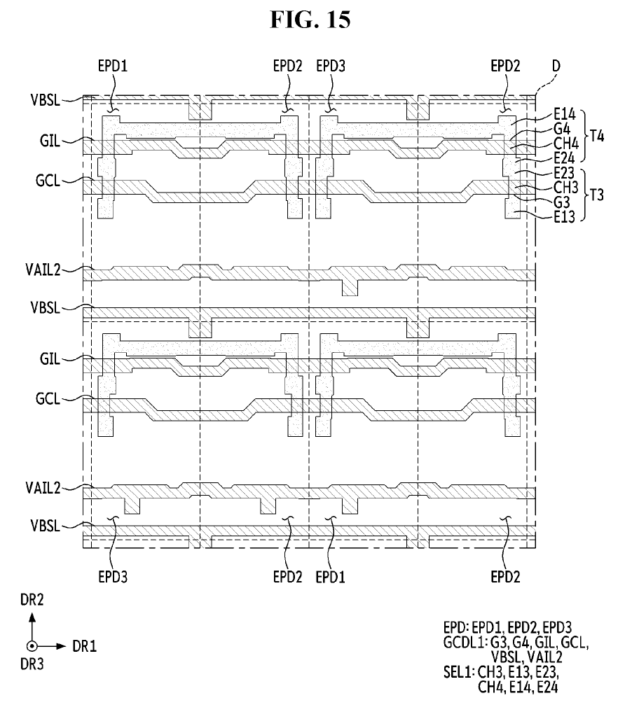

To this end, the circuit layer 120 (refer to FIG. 4) may include a first semiconductor layer SEL1 (refer to FIG. 13) for forming a P-type MOSFET and a second semiconductor layer SEL2 (refer to FIG. 15) for forming an N-type MOSFET.

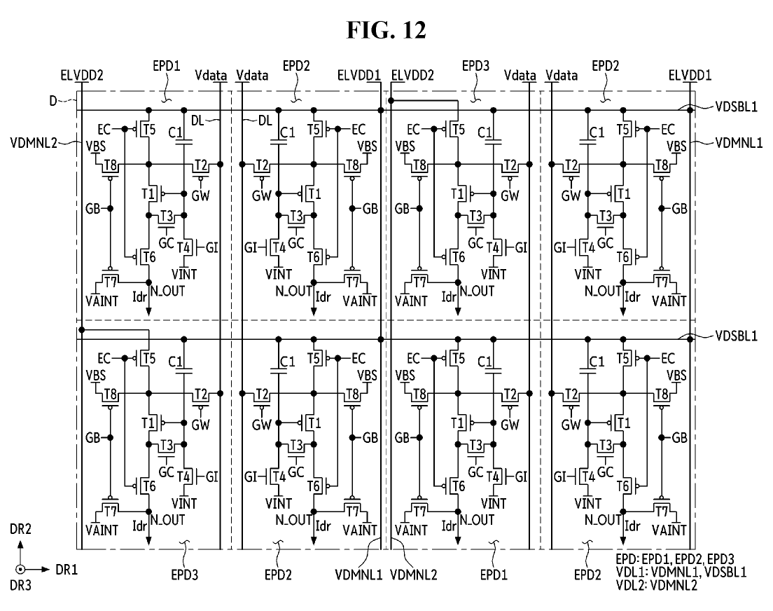

FIG. 12 is a schematic view showing an embodiment of the circuit layer of part D of FIG. 5.

Referring to FIG. 12, the circuit layer 120 of the display device 100 in an embodiment may include the light-emitting pixel drivers EPD arranged in the first and second directions DR1 and DR2 and transmitting the driving current Idr (refer to FIGS. 10 and 11) to the light-emitting elements LE (refer to FIG. 6), a first power main line VDMNL1 extending in the second direction DR2 and transmitting the first power ELVDD1 to at least some (e.g., the first light-emitting pixel driver EPD1 and the second light-emitting pixel driver EPD2) of the light-emitting pixel drivers EPD, and a second power main line VDMNL2 extending in the second direction DR2 and transmitting the second power ELVDD2 different from the first power ELVDD1 to some others (e.g., the third light-emitting pixel driver EPD3) of the light-emitting pixel drivers EPD.

The light-emitting pixel drivers EPD may include a first light-emitting pixel driver EPD1 electrically connected to the first light-emitting element LE1 (refer to FIG. 6), a second light-emitting pixel driver EPD2 electrically connected to the second light-emitting element LE2 (refer to FIG. 6), and a third light-emitting pixel driver EPD3 electrically connected to the third light-emitting element LE3 (refer to FIG. 6).

As mentioned above, the first light-emitting element LE1 (refer to FIG. 6) may be disposed in the first emission area EA1 (refer to FIG. 6) emitting light in the first wavelength band, the second light-emitting element LE2 (refer to FIG. 6) may be disposed in the second emission area EA2 (refer to FIG. 6) emitting light in the second wavelength band lower than the first wavelength band, and the third light-emitting element LE3 (refer to FIG. 6) may be disposed in the third emission area EA3 (refer to FIG. 6) emitting light in the third wavelength band lower than the second wavelength band.

In an embodiment, the first light-emitting element LE1 (refer to FIG. 6) emits light in the first wavelength band, the second light-emitting element LE2 (refer to FIG. 6) emits light in the second wavelength band, and the third light-emitting element LE3 (refer to FIG. 6) may emit light in the third wavelength band, for example.

In an embodiment, each of the first light-emitting element LE1 (refer to FIG. 6) and the second light-emitting element LE2 (refer to FIG. 6) may include one light-emitting stack ESTA (refer to FIG. 7), and the third light-emitting element LE3 (refer to FIG. 6) may include two or more light-emitting stacks ESTA1 and ESTA2 (refer to FIG. 8).

In an embodiment, the first power main line VDMNL1 transmitting the first power ELVDD1 may be electrically connected to the first light-emitting pixel driver EPD1 and the second light-emitting pixel driver EPD2.

That is, the fifth transistor T5 of the first light-emitting pixel driver EPD1 and the fifth transistor T5 of the second light-emitting pixel driver EPD2 may be electrically connected to the first power main line VDMNL1. Accordingly, each of the first light-emitting pixel driver EPD1 and the second light-emitting pixel driver EPD2 may generate the driving current Idr based on the first power ELVDD1.

In addition, the second power main line VDMNL2 transmitting the second power ELVDD2 may be electrically connected to the third light-emitting pixel driver EPD3.

That is, the fifth transistor T5 of the third light-emitting pixel driver EPD3 may be electrically connected to the second power main line VDMNL2. Accordingly, the third light-emitting pixel driver EPD3 may generate the driving current Idr based on the second power source ELVDD2.

In this way, the luminance of the third light-emitting element LE3 may be improved and unnecessary power consumption may be decreased, thereby decreasing the power consumption of the display device 100.

In an embodiment, the first light-emitting pixel driver EPD1 and the third light-emitting pixel driver EPD3 may be arranged alternately in the second direction DR2.

The second light-emitting pixel drivers EPD2 may be arranged side by side in the second direction DR2.

In addition, the second light-emitting pixel driver EPD2 may be disposed between the first light-emitting pixel driver EPD1 and the third light-emitting pixel driver EPD3 in the first direction DR1. That is, the second light-emitting pixel driver EPD2 may be next (adjacent) to one of the first light-emitting pixel driver EPD1 and the third light-emitting pixel driver EPD3 on one side of the first direction DRb, and may be next (adjacent) to a remaining (the other) one of the first light-emitting pixel driver EPD1 and the third light-emitting pixel driver EPD3 on an opposite side of the first direction DR1.

In an embodiment, the first power main line VDMNL1 and the second power main line VDMNL2 may be alternately arranged in the first direction DR1.

Accordingly, the first power main line VDMNL1 may intersect the second light-emitting pixel driver EPD2, and the second power main line VDMNL2 may intersect the first light-emitting pixel driver EPD1 and the third light-emitting pixel driver EPD3.

In an embodiment, the circuit layer 120 may further include a first power sub-line VDSBL1 extending in the first direction DR1 and electrically connected to the first power main line VDMNL1.

That is, the first power line VDL1 for transmitting the first power ELVDD1 may have a mesh structure including the first power main line VDMNL1 and the first power sub-line VDSBL1, so that the first power ELVDD1 may be relatively evenly transmitted to the light-emitting pixel drivers EPD of the display area DA.

In an embodiment, the first capacitor C1 of each of the light-emitting pixel drivers EPD may be electrically connected to the first power sub-line VDSBL1.

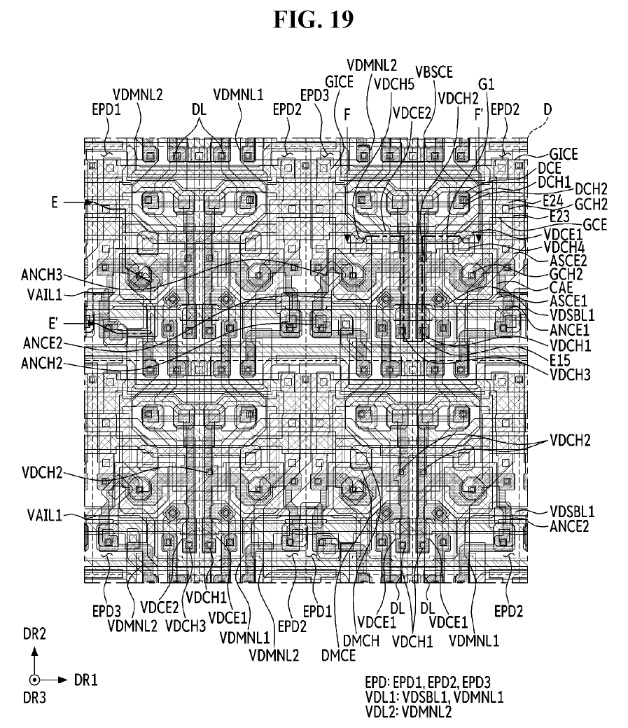

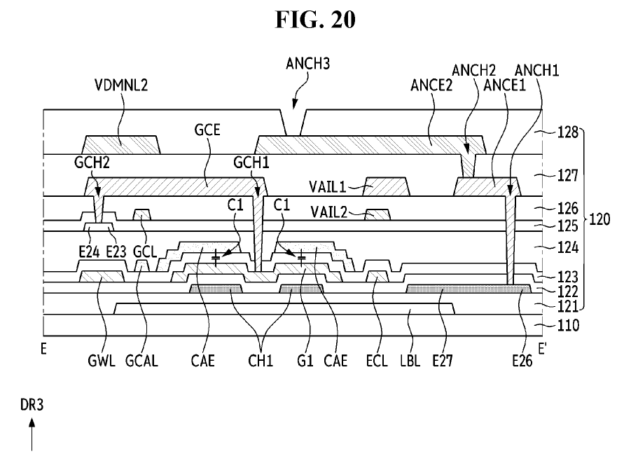

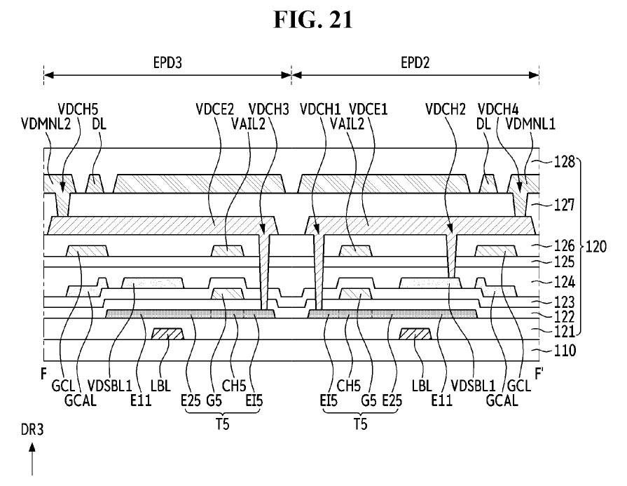

FIGS. 13 to 19 are plan views showing an embodiment of the circuit layer of part D in FIG. 5 in an embodiment of FIG. 12. FIG. 20 is a cross-sectional view taken along line E-E' of FIG. 19. FIG. 21 is a cross-sectional view taken along line F-F' of FIG. 19.

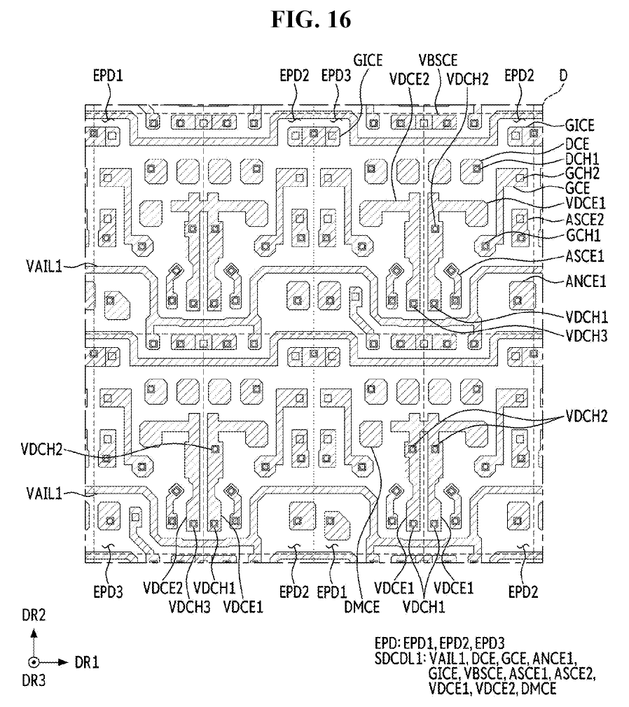

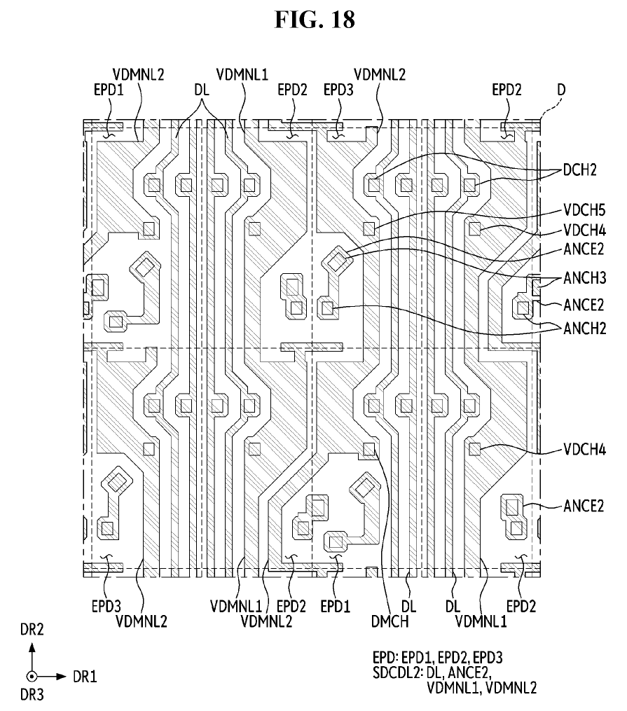

As shown in FIGS. 13 to 21, in an embodiment, the circuit layer 120 of the display device 100 may include the first semiconductor layer SEL1 (refer to FIG. 13) disposed on the substrate 110 (refer to FIGS. 20 and 21), a first inter-insulating layer 124 (refer to FIGS. 20 and 21) disposed on the first semiconductor layer SEL1 (refer to FIG. 13), the second semiconductor layer SEL2 (refer to FIG. 15) disposed on the first inter-insulating layer 124 (refer to FIGS. 20 and 21), a second inter-insulating layer 126 (refer to FIGS. 20 and 21) disposed on the second semiconductor layer SEL2 (refer to FIG. 15), a first source-drain conductive layer SDCDL1 (refer to FIG. 16) disposed on the second inter-insulating layer 126 (refer to FIGS. 20 and 21), a first planarization layer 127 (refer to FIGS. 20 and 21) covering the first source-drain conductive layer SDCDL1 (refer to FIG. 16), a second source-drain conductive layer SDCDL2 (refer to FIG. 18) disposed the first planarization layer 127 (refer to FIGS. 20 and 21), and a second planarization layer 128 (refer to FIGS. 20 and 21) covering the second source-drain conductive layer SDCDL2 (refer to FIG. 18).

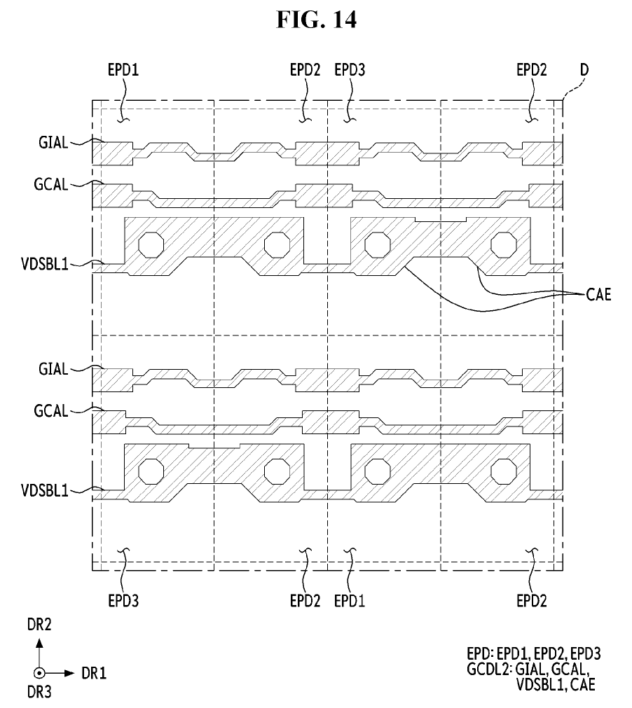

In an embodiment, the circuit layer 120 may further include a first gate insulating layer 122 (refer to FIGS. 20 and 21) covering the first semiconductor layer SEL1 (refer to FIG. 13), a first gate conductive layer GCDL1 (refer to FIG. 13) disposed on the first gate insulating layer 122 (refer to FIGS. 20 and 21), a second gate insulating layer 123 (refer to FIGS. 20 and 21) covering the first gate conductive layer GCDL1 (refer to FIG. 13), and a second gate conductive layer GCDL2 (refer to FIG. 14) disposed between the second gate insulating layer 123 (refer to FIGS. 20 and 21) and the first inter-insulating layer 124 (refer to FIGS. 20 and 21).

In an embodiment, the circuit layer 120 may further include a third gate insulating layer 125 (refer to FIGS. 20 and 21) covering the second semiconductor layer SEL2 (refer to FIG. 15) and a third gate conductive layer GCDL3 (refer to FIG. 15) disposed between the third gate insulating layer 125 (refer to FIGS. 20 and 21) and the second inter-insulating layer 126 (refer to FIGS. 20 and 21).

In other words, the circuit layer 120 may include the first semiconductor layer SEL1 disposed on the substrate 110, the first gate insulating layer 122 covering the first semiconductor layer SEL1, the first gate conductive layer GCDL1 disposed on the first gate insulating layer 122, the second gate insulating layer 123 covering the first gate conductive layer GCDL1, the second gate conductive layer GCDL2 disposed on the second gate insulating layer 123, the first inter-insulating layer 124 covering the second gate conductive layer GCDL2, the second semiconductor layer SEL2 disposed on the first inter-insulating layer 124, the third gate insulating layer 125 covering the second semiconductor layer SEL2, the third gate conductive layer GCDL3 disposed on the third gate insulating layer 125, a second inter-insulating layer 126 covering the third gate conductive layer GCDL3, the first source-drain conductive layer SDCDL1 disposed on the second inter-insulating layer 126, the first planarization layer 127 covering the first source-drain conductive layer SDCDL1, the second source-drain conductive layer SDCDL2 disposed on the first planarization layer 127, and the second planarization layer 128 covering the second source-drain conductive layer SDCDL2.

In an embodiment, the circuit layer 120 may further include a light-blocking layer LBL (refer to FIGS. 13, 20, and 21) disposed on the substrate 110, and a buffer layer 121 (refer to FIGS. 20 and 21) covering the light-blocking layer LBL. In this case, the first semiconductor layer SEL1 (refer to FIG. 13) may be disposed on the buffer layer 121.

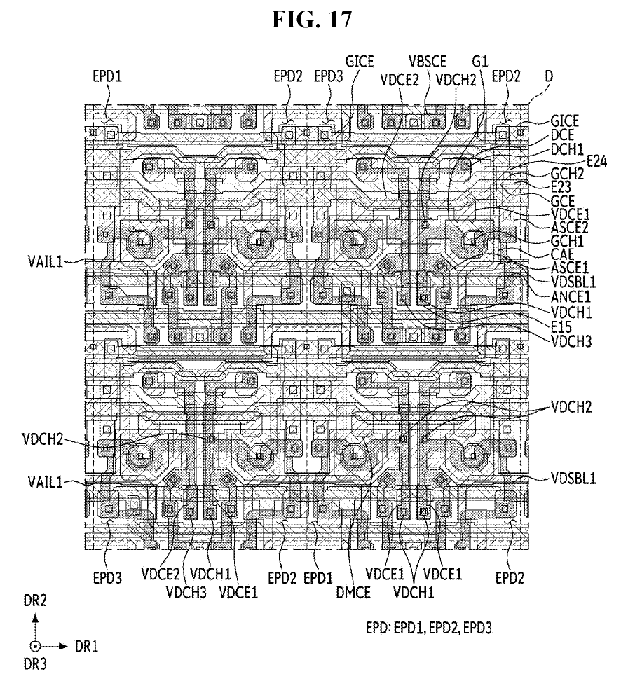

FIG. 13 shows the first semiconductor layer SEL1 and the first gate conductive layer GCDL1 of the circuit layer of part D in FIG. 5. FIG. 14 shows the second gate conductive layer GCDL2 of the circuit layer of part D in FIG. 5. FIG. 15 shows the second semiconductor layer SEL2 and the third gate conductive layer GCDL3 of the circuit layer of part D in FIG. 5. FIG. 16 shows the first source-drain conductive layer SDCDL1 of the circuit layer of part D in FIG. 5. FIG. 17 shows the first semiconductor layer SEL1, the first gate conductive layer GCDL1, the second gate conductive layer GCDL2, the second semiconductor layer SEL2, the third gate conductive layer GCDL3, and the first source-drain conductive layer SDCDL1 of the circuit layer of part D in FIG. 5. FIG. 18 shows the second source-drain conductive layer SDCDL2 of the circuit layer in part D in FIG. 5. FIG. 19 shows the first semiconductor layer SEL1, the first gate conductive layer GCDL1, the second gate conductive layer GCDL2, the second semiconductor layer SEL2, the third gate conductive layer GCDL3, the first source-drain conductive layer SDCDL1, and the second source-drain conductive layer SDCDL2 of the circuit layer of part D in FIG. 5.

As mentioned above, in each of the light-emitting pixel drivers EPD, the first transistor T1, the second transistor T2, the fifth transistor T5, the sixth transistor T6, the seventh transistor T7, and the eighth transistor T8 may be formed as P-type MOSFETs. Further, in each of the light-emitting pixel drivers EPD, the third transistor T3 and the fourth transistor T4 may be formed as N-type MOSFETs.

Referring to FIG. 13, the channel portions CH1, CH2, CH5, CH6, CH7 and CH8, first electrodes E11, E12, E15, E16, E17, and E18, and the second electrodes E21, E22, E25, E26, E27, and E28 of the first transistor T1, second transistor T2, fifth transistor T5, sixth transistor T6, seventh transistor T7, and eighth transistor T8 may be disposed in the first semiconductor layer SEL1.

The channel portion CH1 of the first transistor T1 may overlap the light-blocking layer LBL in the third direction DR3.

A first electrode E11 of the first transistor T1 may be connected to the channel portion CH1 of the first transistor T1, a second electrode E22 of the second transistor T2 and a second electrode E25 of the fifth transistor T5.

A second electrode E21 of the first transistor T1 may be connected to the channel portion CH1 of the first transistor T1 and a first electrode E16 of the sixth transistor T6.

The channel portion CH2 of the second transistor T2 may be connected to each of a first electrode E12 of the second transistor T2 and the second electrode E22 of the second transistor T2.

The channel portion CH5 of the fifth transistor T5 may be connected to each of a first electrode E15 of the fifth transistor T5 and the second electrode E25 of the fifth transistor T5.

The channel portion CH6 of the sixth transistor T6 may be connected to each of the first electrode E16 of the sixth transistor T6 and a second electrode E26 of the sixth transistor T6.

The second electrode E26 of the sixth transistor T6 may be connected to a second electrode E27 of the seventh transistor T7.

The channel portion CH7 of the seventh transistor T7 may be connected to each of a first electrode E17 of the seventh transistor T7 and the second electrode E27 of the seventh transistor T7.

The channel portion CH8 of the eighth transistor T8 may be connected to each of a first electrode E18 of the eighth transistor T8 and a second electrode E28 of the eighth transistor T8.

The gate electrodes G1, G2, G5, G6, G7, and G8 of the first transistor T1, the second transistor T2, the fifth transistor T5, the sixth transistor T6, the seventh transistor T7, and the eighth transistor T8 may be disposed in the first gate conductive layer GCDL1.

In the first transistor T1, the second transistor T2, the fifth transistor T5, the sixth transistor T6, the seventh transistor T7, and the eighth transistor T8, the gate electrodes G1, G2, G5, G6, G7, and G8 may overlap the channel portions CH1, CH2, CH5, CH6, CH7, and CH8, respectively.

Each of the scan write line GWL, the emission control line ECL, the bias control line GBL, and the gate initialization voltage line VIL may extend in the first direction DR1 and may be disposed in the first gate conductive layer GCDL1.

The gate electrode G2 of the second transistor T2 may be a portion of the scan write line GWL, which overlaps the channel portion CH2 of the second transistor T2.

The gate electrode G5 of the fifth transistor T5 may be a portion of the emission control line ECL, which overlaps the channel portion CH5 of the fifth transistor T5.

The gate electrode G6 of the sixth transistor T6 may be another portion of the emission control line ECL, which overlaps the channel portion CH6 of the sixth transistor T6.

The gate electrode G7 of the seventh transistor T7 may be a portion of the bias control line GBL, which overlaps the channel portion CH7 of the seventh transistor T7.

The gate electrode G8 of the eighth transistor T8 may be another portion of the bias control line GBL, which overlaps the channel portion CH8 of the eighth transistor T8.

As shown in FIGS. 14 and 17, each of the light-emitting pixel drivers EPD may include a capacitor electrode CAE disposed in the second gate conductive layer GCDL2 and overlapping the gate electrode G1 of the first transistor T1 in the third direction DR3.

As shown in FIG. 14, the first power sub-line VDSBL1 may extend in the first direction DR1 and may be disposed in the second gate conductive layer GCDL2.

In an embodiment, the capacitor electrode CAE may be a portion of the first power sub-line VDSBL1 transmitting the first power ELVDD1 (refer to FIG. 12), which overlaps the gate electrode G1 of the first transistor T1.

As shown in FIG. 20, the first capacitor electrode C1 may be formed in a region where the gate electrode G1 of the first transistor T1 overlaps the capacitor electrode CAE in the third direction DR3.

In an embodiment, since the capacitor electrode CAE of each of the light-emitting pixel drivers EPD is electrically connected to the first power sub-line VDSBL1 transmitting the first power ELVDD1 (refer to FIG. 12), the first capacitor C1 (refer to FIG. 12) of each of the light-emitting pixel drivers EPD may be electrically connected between the first power line VDL1 (refer to FIG. 12) and the gate electrode G1 of the first transistor T1.

As shown in FIG. 14, the circuit layer 120 may further include a scan initialization auxiliary line GIAL and a gate control auxiliary line GCAL disposed in the second gate conductive layer GCDL2.

Each of the scan initialization auxiliary line GIAL and the gate control auxiliary line GCAL may extend in the first direction DR1.

As shown in FIG. 15, channel portions CH3 and CH4, first electrodes E13 and E14, and second electrodes E23 and E24 of the respective third transistor T3 and fourth transistor T4 may be disposed in the second semiconductor layer SEL2.

The channel portion CH3 of the third transistor T3 may be connected to each of the first electrode E13 of the third transistor T3 and the second electrode E23 of the third transistor T3.

The channel portion CH4 of the fourth transistor T4 may be connected to each of the first electrode E14 of the fourth transistor T4 and the second electrode E24 of the fourth transistor T4.

The second electrode E23 of the third transistor T3 may be connected to the second electrode E24 of the fourth transistor T4.

The gate electrode G3 of the third transistor T3 and the gate electrode G4 of the fourth transistor T4 may be disposed in the third gate conductive layer GCDL3.

In the third transistor T3 and the fourth transistor T4, the gate electrodes G3 and G4 may overlap the channel portions CH3 and CH4, respectively.

Each of the scan initialization line GIL, the gate control line GCL, the bias voltage line VBSL, and the second anode initialization voltage line VAIL2 may extend in the first direction DR1 and may be disposed in the third gate conductive layer GCDL3.

The gate electrode G3 of the third transistor T3 may be a portion of the gate control line GCL, which overlaps the channel portion CH3 of the third transistor T3.

The gate electrode G4 of the fourth transistor T4 may be a portion of the scan initialization line GIL, which overlaps the channel portion CH4 of the fourth transistor T4.

Referring to FIG. 16, the first anode initialization voltage line VAIL1 may extend in the first direction DR1 and may be disposed in the first source-drain conductive layer SDCDL1.

Each of the light-emitting pixel drivers EPD may include a data connection electrode DCE, a gate connection electrode GCE, a first anode connection electrode ANCE1, a scan initialization connection electrode GICE, a bias voltage connection electrode VBSCE, a first auxiliary connection electrode ASCE1, and a second auxiliary connection electrode ASCE2.

Each of the first light-emitting pixel driver EPD1 and the second light-emitting pixel driver EPD2 may include a first power connection electrode VDCE1.

The third light-emitting pixel driver EPD3 may include a second power connection electrode VDCE2.

The first power connection electrode VDCE1 of the first light-emitting pixel driver EPD1 and the first power connection electrode VDCE1 of the second light-emitting pixel driver EPD2 that are next (adjacent) to each other in the first direction DR1 may be connected to each other.

The first light-emitting pixel driver EPD1 may further include a dummy connection electrode DMCE spaced apart from the first power connection electrode VDCE1.

In the first light-emitting pixel driver EPD1 and the second light-emitting pixel driver EPD2 next (adjacent) to each other in the first direction DR1, the first power connection electrode VDCE1 and the dummy connection electrode DMCE of the first light-emitting pixel driver EPD1 may be symmetrical with parts of the first power connection electrode VDCE1 of the second light-emitting pixel driver EPD2 with respect to the boundary between the first light-emitting pixel driver EPD1 and the second light-emitting pixel driver EPD2.

Each of the data connection electrode DCE, the gate connection electrode GCE, the first anode connection electrode ANCE1, the scan initialization connection electrode GICE, the bias voltage connection electrode VBSCE, the first auxiliary connection electrode ASCE1, the second auxiliary connection electrode ASCE2, the first power connection electrode VDCE1, the second power connection electrode VDCE2, and the dummy connection electrode DMCE may be disposed in the first source-drain conductive layer SDCDL1 in an island shape.

As shown in FIGS. 16 and 17, the data connection electrode DCE may be electrically connected to the first electrode E12 (refer to FIG. 13) of the second transistor T2 (refer to FIG. 13).

The first anode connection electrode ANCE1 may be electrically connected to the second electrode E26 (refer to FIG. 13) of the sixth transistor T6 (refer to FIG. 13) and the second electrode E27 (refer to FIG. 13) of the seventh transistor T7 (refer to FIG. 13) through a first anode connection hole ANCH1.

The scan initialization connection electrode GICE may be electrically connected to the gate initialization voltage line VIL (refer to FIG. 13) and the first electrode E14 (refer to FIG. 15) of the fourth transistor T4 (refer to FIG. 15).

The bias voltage connection electrode VBSCE may be electrically connected to the bias voltage line VBSL (refer to FIG. 15) and the first electrode E18 (refer to FIG. 13) of the eighth transistor T8 (refer to FIG. 13). That is, the first electrode E18 (refer to FIG. 13) of the eighth transistor T8 (refer to FIG. 13) may be electrically connected to the bias voltage line VBSL (refer to FIG. 15) through the bias voltage connection electrode VBSCE.

The first auxiliary connection electrode ASCE1 may be electrically connected to the first electrode E11 (refer to FIG. 13) of the first transistor T1 (refer to FIG. 13), the second electrode E22 (refer to FIG. 13) of the second transistor T2 (refer to FIG. 13), the second electrode E25 of the fifth transistor T5 (refer to FIG. 13), and the second electrode E28 (refer to FIG. 13) of the eighth transistor T8 (refer to FIG. 13). That is, the second electrode E28 (refer to FIG. 13) of the eighth transistor T8 (refer to FIG. 13) may be electrically connected to the first electrode E11 (refer to FIG. 13) of the first transistor T1 (refer to FIG. 13) and the second electrode E25 of the fifth transistor T5 (refer to FIG. 13) through the first auxiliary connection electrode ASCE1.

The second auxiliary connection electrode ASCE2 may be electrically connected to the second electrode E21 (refer to FIG. 13) of the first transistor T1 (refer to FIG. 13) and the first electrode E13 (refer to FIG. 15) of the third transistor T3 (refer to FIG. 15). That is, the first electrode E13 (refer to FIG. 15) of the third transistor T3 (refer to FIG. 15) may be electrically connected to the second electrode E21 (refer to FIG. 13) of the first transistor T1 (refer to FIG. 13) through the second auxiliary connection electrode ASCE2.

The gate connection electrode GCE may be electrically connected to the gate electrode G1 of the first transistor T1 (refer to FIG. 13) through a first gate connection hole GCH1, and may be electrically connected to the second electrode E23 (refer to FIG. 15) of the third transistor T3 (refer to FIG. 15) and the second electrode E24 (refer to FIG. 15) of the fourth transistor T4 (refer to FIG. 15) through a second gate connection hole GCH2.

The first power connection electrode VDCE1 may be electrically connected to the first electrode E15 of the fifth transistor T5 (refer to FIG. 13) of each of the first and second light-emitting pixel drivers EPD1 and EPD2 through a first power connection hole VDCH1.

The first power connection electrode VDCE1 may be electrically connected to the first power sub-line VDSBL1 through a second power connection hole VDCH2.

The second power connection electrode VDCE2 may be electrically connected to the first electrode E15 of the fifth transistor T5 (refer to FIG. 13) of the third light-emitting pixel driver EPD3 through a third power connection hole VDCH3.

Referring to FIG. 18, each of the data line DL, the first power main line VDMNL1, and the second power main line VDMNL2 may extend in the second direction DR2 and may be disposed in the second source-drain conductive layer SDCDL2.

Each of the light-emitting pixel drivers EPD may further include a second anode connection electrode ANCE2 disposed in the second source-drain conductive layer SDCDL2.

As shown in FIGS. 18 and 19, the first power line VDL1 may have a mesh shape including the first power sub-line VDSBL1 extending in the first direction DR1 and the first power main line VDMNL1 extending in the second direction DR2.

Accordingly, the first power ELVDD1 (refer to FIG. 12) may be relatively evenly transmitted to the light-emitting pixel drivers EPD of the display area DA.

According to the embodiment of FIGS. 12 and 19, the second power line VDL2 may include only the second power main line VDMNL2 extending in the second direction DR2.

The data line DL may be electrically connected to the data connection electrode DCE through a second data connection hole DCH2.

Accordingly, the first electrode E12 (refer to FIG. 13) of the second transistor T2 (refer to FIG. 13) may be electrically connected to the data line DL through the data connection electrode DCE.

The second anode connection electrode ANCE2 may be electrically connected to the first anode connection electrode ANCE1 through a second anode connection hole ANCH2, and may be electrically connected to one of the light-emitting elements LE (refer to FIG. 6) through a third anode connection hole ANCH3.

Accordingly, the second electrode E26 (refer to FIG. 13) of the sixth transistor T6 (refer to FIG. 13) and the second electrode E27 (refer to FIG. 13) of the seventh transistor T7 (refer to FIG. 13) may be electrically connected to the anode electrode 131 (refer to FIG. 6) of one of the light-emitting elements LE (refer to FIG. 6) through the first anode connection electrode ANCE1 and the second anode connection electrode ANCE2.

The first power main line VDMNL1 may be electrically connected to the first power connection electrode VDCE1 through a fourth power connection hole VDCH4.

Accordingly, each of the first electrode E15 of the fifth transistor T5 (refer to FIG. 13) of the first light-emitting pixel driver EPD1, the first electrode E15 of the fifth transistor T5 (refer to FIG. 13) of the second light-emitting pixel driver EPD2, and the first power sub-line VDSBL1 may be electrically connected to the first power main line VDMNL1 through the first power connection electrode VDCE1.

The second power main line VDMNL2 may be electrically connected to the second power connection electrode VDCE2 through a fifth power connection hole VDCH5.

Accordingly, the first electrode E15 of the fifth transistor T5 (refer to FIG. 13) of the third light-emitting pixel driver EPD3 may be electrically connected to the second power main line VDMNL2 through the second power connection electrode VDCE2.

In addition, the second power main line VDMNL2 may be electrically connected to the dummy connection electrode DMCE through a dummy connection hole DMCH.

As shown in FIG. 20, the light-blocking layer LBL may be disposed on the substrate 110 and may be covered with the buffer layer 121.

The channel portion CH1 of the first transistor T1 (refer to FIG. 13), the second electrode E26 of the sixth transistor T6 (refer to FIG. 13), and the second electrode E27 of the seventh transistor T7 (refer to FIG. 13) may be disposed on the buffer layer 121 and may be covered with the first gate insulating layer 122.

The gate electrode G1 of the first transistor T1 (refer to FIG. 13), the scan write line GWL, and the emission control line ECL may be disposed on the first gate insulating layer 122 and may be covered with the second gate insulating layer 123.

The channel portion CH1 of the first transistor T1 (refer to FIG. 13) may overlap the gate electrodes G1 of the first transistor T1 (refer to FIG. 13) in the third direction DR3.

The channel portion CH1 of the first transistor T1 (refer to FIG. 13) may be disposed between the light-blocking layer LBL and the gate electrode G1 of the first transistor T1 (refer to FIG. 13) in the third direction DR3.

The capacitor electrode CAE and the gate control auxiliary line GCAL may be disposed on the second gate insulating layer 123 and may be covered with the first inter-insulating layer 124.

The first capacitor C1 may be formed by the second gate insulating layer 123 in a region where the gate electrode G1 of the first transistor T1 (refer to FIG. 13) and the capacitor electrode CAE overlap each other in the third direction DR3.

The second electrode E23 of the third transistor T3 (refer to FIG. 15) and the second electrode E24 of the fourth transistor T4 (refer to FIG. 15) may be disposed on the first inter-insulating layer 124 and covered with the third gate insulating layer 125.

The gate control line GCL and the second anode initialization voltage line VAIL2 may be disposed on the third gate insulating layer 125 and covered with the second inter-insulating layer 126.

The gate control line GCL may overlap the gate control auxiliary line GCAL in the third direction DR3.

The gate connection electrode GCE, the first anode initialization voltage line VAIL1, and the first anode connection electrode ANCE1 may be disposed on the second inter-insulating layer 126 and covered with the first planarization layer 127.

The gate connection electrode GCE may be electrically connected to the gate electrode G1 of the first transistor T1 (refer to FIG. 13) through the first gate connection hole GCH1, and may be electrically connected to the second electrode E23 of the third transistor T3 (refer to FIG. 15) and the second electrode E24 of the fourth transistor T4 (refer to FIG. 15) through the second gate connection hole GCH2.

The first anode connection electrode ANCE1 may be electrically connected to the second electrode E26 of the sixth transistor T6 (refer to FIG. 13) and the second electrode E27 of the seventh transistor T7 (refer to FIG. 13) through the first anode connection hole ANCH1.

The second power main line VDMNL2 and the second anode connection electrode ANCE2 may be disposed on the first planarization layer 127 and covered with the second planarization layer 128.

The second anode connection electrode ANCE2 may be electrically connected to the first anode connection electrode ANCE1 through the second anode connection hole ANCH2, and may be electrically connected to one of the light-emitting elements LE (refer to FIG. 6) through the third anode connection hole ANCH3.

Accordingly, the second electrode E26 of the sixth transistor T6 (refer to FIG. 13) and the second electrode E27 of the seventh transistor T7 (refer to FIG. 13) may be electrically connected to the anode electrode 131 (refer to FIG. 6) of one of the light-emitting elements LE (refer to FIG. 6) through the first anode connection electrode ANCE1 and the second anode connection electrode ANCE2.

As shown in FIG. 21, the channel portion CH5, the first electrode E15, and the second electrode E25 of the fifth transistor T5, and the first electrode E11 of the first transistor T1 (refer to FIG. 13) may be disposed on the buffer layer 121 and covered with the first gate insulating layer 122.

The gate electrode G5 of the fifth transistor T5 may be disposed on the first gate insulating layer 122 and covered with the second gate insulating layer 123.

The gate electrode G5 of the fifth transistor T5 may overlap the channel portion CH5 of the fifth transistor T5 in the third direction DR3.

The first power sub-line VDSBL1 and the gate control auxiliary line GCAL may be disposed on the second gate insulating layer 123 and covered with the first inter-insulating layer 124.

The first power sub-line VDSBL1 may intersect the second light-emitting pixel driver EPD2 and the third light-emitting pixel driver EPD3.

The second light-emitting pixel driver EPD2 may include the first power connection electrode VDCE1.

The third light-emitting pixel driver EPD3 may include the second power connection electrode VDCE2.

The first power connection electrode VDCE1 and the second power connection electrode VDCE2 may be disposed on the second inter-insulating layer 126 and covered with the first planarization layer 127.

The first power connection electrode VDCE1 may be electrically connected to the first electrode E15 of the fifth transistor T5 of the second light-emitting pixel driver EPD2 through the first power connection hole VDCH1, and may be electrically connected to the first power sub-line VDSBL1 through the second power connection hole VDCH2.

The second power connection electrode VDCE2 may be electrically connected to the first electrode E15 of the fifth transistor T5 of the third light-emitting pixel driver EPD3 through the third power connection hole VDCH3.

The data line DL, the first power main line VDMNL1, and the second power main line VDMNL2 may be disposed on the first planarization layer 127 and covered with the second planarization layer 128.

The first power main line VDMNL1 may be electrically connected to the first power connection electrode VDCE1 through the fourth power connection hole VDCH4.

Accordingly, the first power sub-line VDSBL1 and the first electrode E15 of the fifth transistor T5 of the second light-emitting pixel driver EPD2 may be electrically connected to the first power main line VDMNL1 through the first power connection electrode VDCE1.

The second power main line VDMNL2 may be electrically connected to the second power connection electrode VDCE2 through the fifth power connection hole VDCH5.

Accordingly, the first electrode E15 of the fifth transistor T5 of the third light-emitting pixel driver EPD3 may be electrically connected to the second power main line VDMNL2 through the second power connection electrode VDCE2.

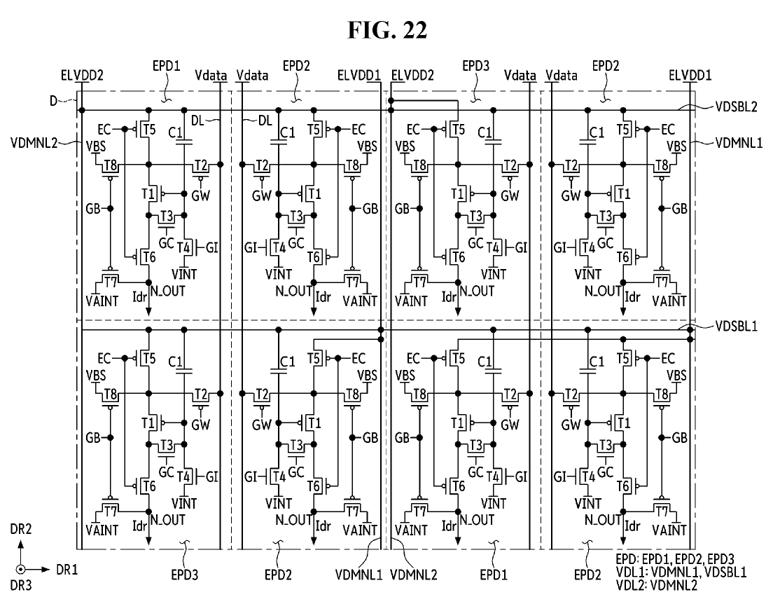

FIG. 22 is a schematic view showing an embodiment of the circuit layer of part D of FIG. 5.

The display device 100 of an embodiment shown in FIG. 22 is substantially the same as or similar to the display device 100 of an embodiment shown in FIG. 12 except that the circuit layer 120 extends in the first direction DR1 and further includes a second power sub-line VDSBL2 electrically connected to the second power main line VDMNL2, and thus redundant description is omitted below.

As shown in FIG. 22, in an embodiment, the circuit layer 120 may include the first power sub-line VDSBL1 extending in the first direction DR1 and electrically connected to the first power main line VDMNL1, and the second power sub-line VDSBL2 extending in the first direction DR1 and electrically connected to the second power main line VDMNL2.

The first power sub-line VDSBL1 and the second power sub-line VDSBL2 may be alternately arranged in the second direction DR2.

Accordingly, one of two light-emitting pixel drivers EPD next (adjacent) to each other in the second direction DR2 (e.g., the light-emitting pixel driver disposed in the second row of FIG. 22) may intersect the first power sub-line VDSBL1, and a remaining (the other) light-emitting pixel driver (e.g., the light-emitting pixel driver disposed in the first row of FIG. 22) may intersect the second power sub-line VDSBL2.

The first capacitor C1 of one of the two light-emitting pixel drivers EPD next (adjacent) to each other in the second direction DR2 (e.g., the light-emitting pixel driver disposed in the second row of FIG. 22) may be electrically connected to the first power sub-line VDSBL1.

Further, the first capacitor C1 of a remaining (the other) of the two light-emitting pixel drivers EPD next (adjacent) to each other in the second direction DR2 (e.g., the light-emitting pixel driver disposed in the first row of FIG. 22) may be electrically connected to the second power sub-line VDSBL2.

In this way, not only the first power line VDL1 has a mesh shape, but the second power line VDL2 transmitting the second power ELVDD2 also has a mesh shape including the second power sub-line VDSBL2 extending in the first direction DR1 and the second power main line VDMNL2 extending in the second direction DR2, so that the second power ELVDD2 may be relatively evenly transmitted to the display area DA.

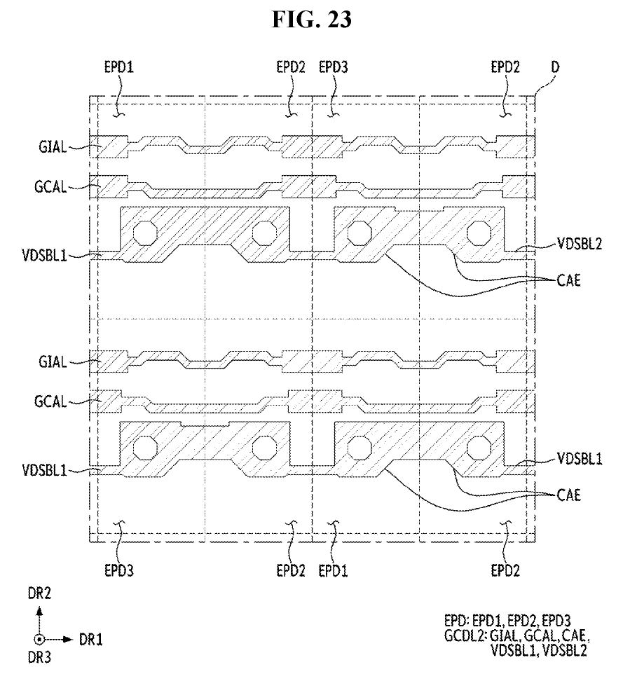

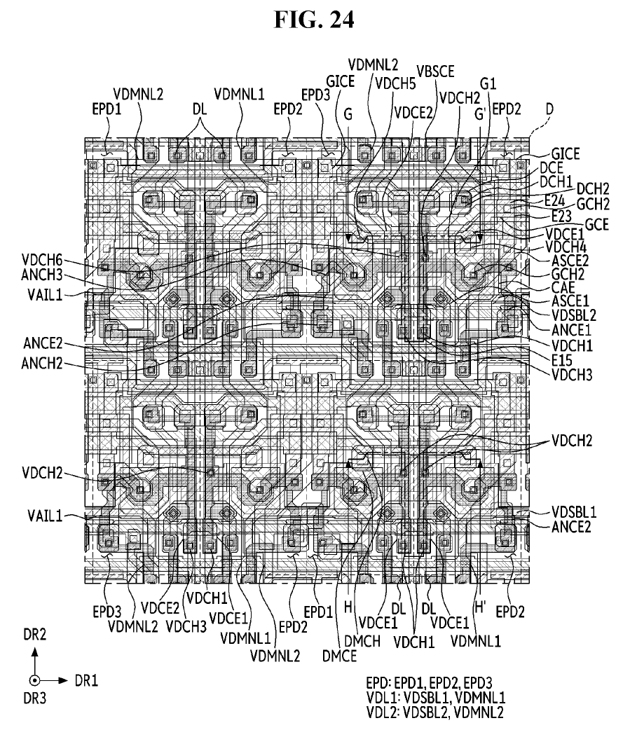

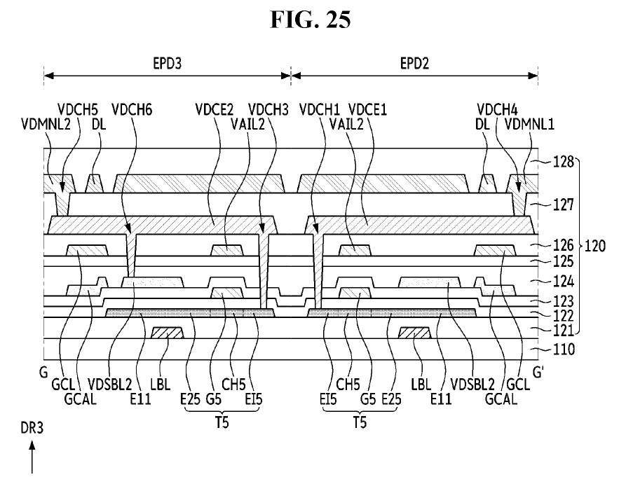

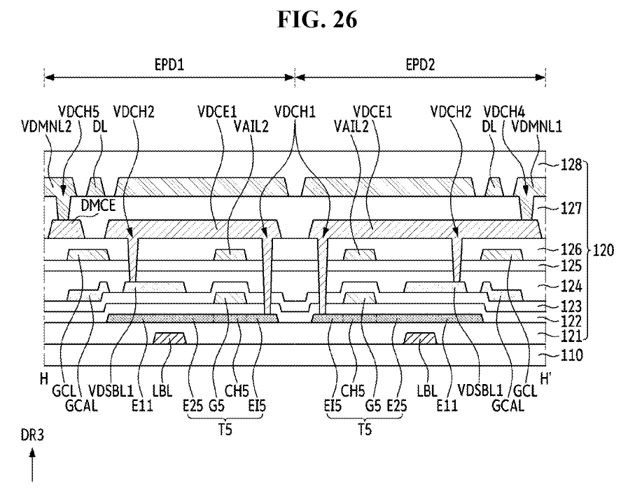

FIGS. 23 and 24 are plan views showing an embodiment of the circuit layer of part D of FIG. 5. FIG. 25 is a cross-sectional view taken along line G-G' of FIG. 24. FIG. 26 is a cross-sectional view taken along line H-H' of FIG. 24.

In an embodiment shown in FIGS. 23 and 24, the remainder of the circuit layer 120 except for the second gate conductive layer GCDL2, that is, the first semiconductor layer SEL1, the first gate conductive layer GCDL1, the second semiconductor layer SEL2, the third gate conductive layer GCDL3, the first source-drain conductive layer SDCDL1, and the second source-drain conductive layer SDCDL2 are substantially the same as or similar to those in the embodiment shown in FIGS. 13, 15, 16, and 18, and thus redundant description is omitted below.

FIG. 23 illustrates an embodiment of the second gate conductive layer GCDL2 of the circuit layer of part D in FIG. 5 according to FIG. 22. FIG. 25 shows an embodiment of the first semiconductor layer SEL1, the first gate conductive layer GCDL1, the second gate conductive layer GCDL2, the second semiconductor layer SEL2, the third gate conductive layer GCDL3, the first source-drain conductive layer SDCDL1, and the second source-drain conductive layer SDCDL2 of the circuit layer of part D in FIG. 5 according to FIG. 22.

As shown in FIG. 23, in an embodiment, the first power sub-line VDSBL1 and the second power sub-line VDSBL2 may be disposed in the second gate conductive layer GCDL2 and may extend in the first direction DR1.

Each of the light-emitting pixel drivers EPD may include the capacitor electrode CAE disposed in the second gate conductive layer GCDL2.

The capacitor electrode CAE of each of the light-emitting pixel drivers EPD may be a part of one of the first power sub-line VDSBL1 and the second power sub-line VDSBL2.

In an embodiment, between two light-emitting pixel drivers EPD next (adjacent) to each other in the second direction DR2, the capacitor electrode CAE of one light-emitting pixel driver (e.g., the light-emitting pixel driver disposed in the second row of FIG. 22) intersecting the first power sub-line VDSBL1 may be a part of the first power sub-line VDSBL1.

Between the two light-emitting pixel drivers EPD next (adjacent) to each other in the second direction DR2, the capacitor electrode CAE of a remaining (the other) light-emitting pixel driver (e.g., the light-emitting pixel driver disposed in the first row of FIG. 22) intersecting the second power sub-line VDSBL2 may be a part of the second power sub-line VDSBL2.

As described above with reference to FIG. 20, in each of the light-emitting pixel drivers EPD, the capacitor electrode CAE overlaps the gate electrode G1 of the first transistor T1 (refer to FIG. 22) in the third direction DR3, so that the first capacitor C1 may be formed by a region where the capacitor electrode CAE and the gate electrode G1 of the first transistor T1 (refer to FIG. 22) overlap each other in the third direction DR3.

As shown in FIGS. 24 and 26, in an embodiment, the first power connection electrode VDCE1 may be electrically connected to the first electrode E15 of the fifth transistor T5 (refer to FIG. 22) of the first light-emitting pixel driver EPD1 and the first electrode E15 of the fifth transistor T5 (refer to FIG. 22) of the second light-emitting pixel driver EPD2 through the first power connection hole VDCH1 and may be electrically connected to the first power sub-line VDSBL1 through the second power connection hole VDCH2.

The first power main line VDMNL1 may be electrically connected to the first power connection electrode VDCE1 through a fourth power connection hole VDCH4.

Accordingly, the first power sub-line VDSBL1, the first electrode E15 of the fifth transistor T5 (refer to FIG. 22) of the first light-emitting pixel driver EPD1, and the first electrode E15 of the fifth transistor T5 (refer to FIG. 22) of the second light-emitting pixel driver EPD2 may be electrically connected to the first power main line VDMNL1 through the first power connection electrode VDCE1.

The first light-emitting pixel driver EPD1 may further include the dummy connection electrode DMCE disposed in an island shape on the second inter-insulating layer 126 and spaced apart from the first power connection electrode VDCE1.

As shown in FIGS. 24 and 25, in an embodiment, the second power connection electrode VDCE2 may be electrically connected to the first electrode E15 of the fifth transistor T5 (refer to FIG. 22) of the third light-emitting pixel driver EPD3 through the third power connection hole VDCH3, and may be electrically connected to the second power sub-line VDSBL2 through a sixth power connection hole VDCH6.

The second power main line VDMNL2 may be electrically connected to the second power connection electrode VDCE2 through a fifth power connection hole VDCH5.

Accordingly, the second power sub-line VDSBL2 and the first electrode E15 of the fifth transistor T5 (refer to FIG. 22) of the third light-emitting pixel driver EPD3 may be electrically connected to the second power main line VDMNL2 through the second power connection electrode VDCE2.

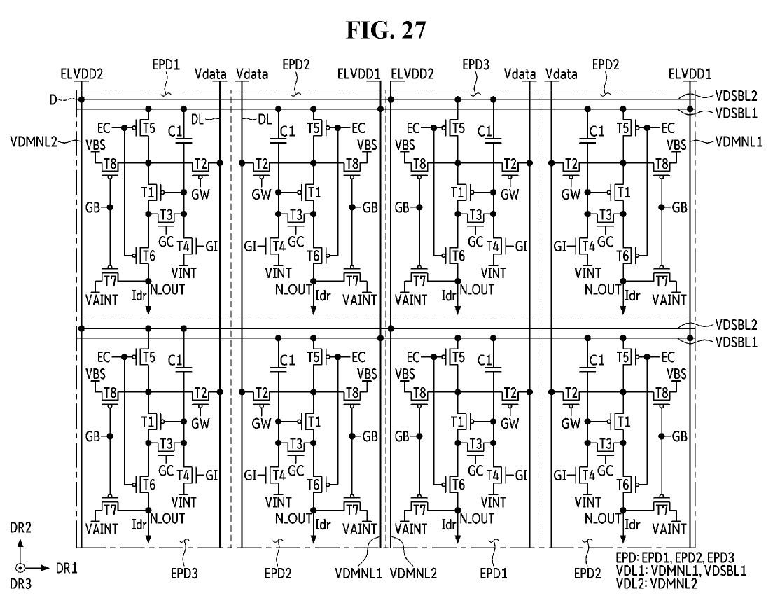

FIG. 27 is a schematic view showing an embodiment of the circuit layer of part D of FIG. 5.

The display device 100 of an embodiment shown in FIG. 27 is substantially the same as or similar to the display device 100 of the embodiment shown in FIG. 22 except that each of the light-emitting pixel drivers EPD intersects the first power sub-line VDSBL1 and the second power sub-line VDSBL2, the first capacitor C1 of each of the first light-emitting pixel driver EPD1 and the second light-emitting pixel driver EPD2 is electrically connected to the first power main line VDMNL1, and the first capacitor C1 of the third light-emitting pixel driver EPD3 is electrically connected to the second power main line VDMNL2, and thus redundant description is omitted below.

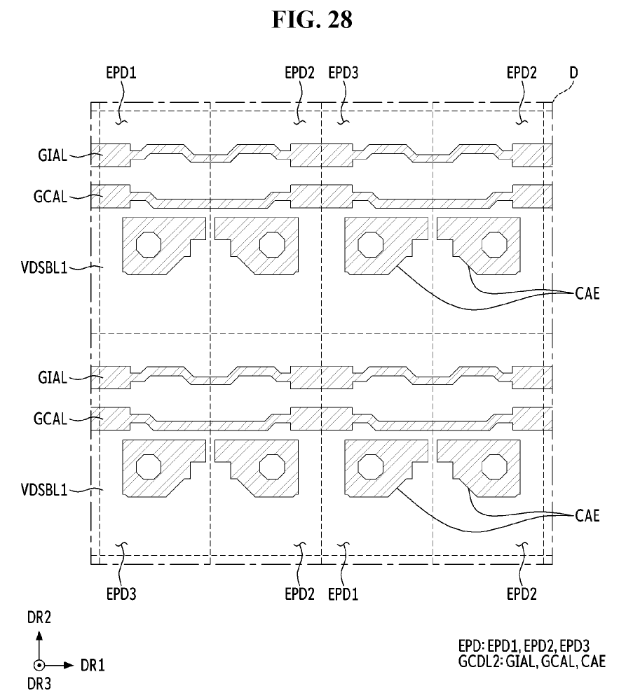

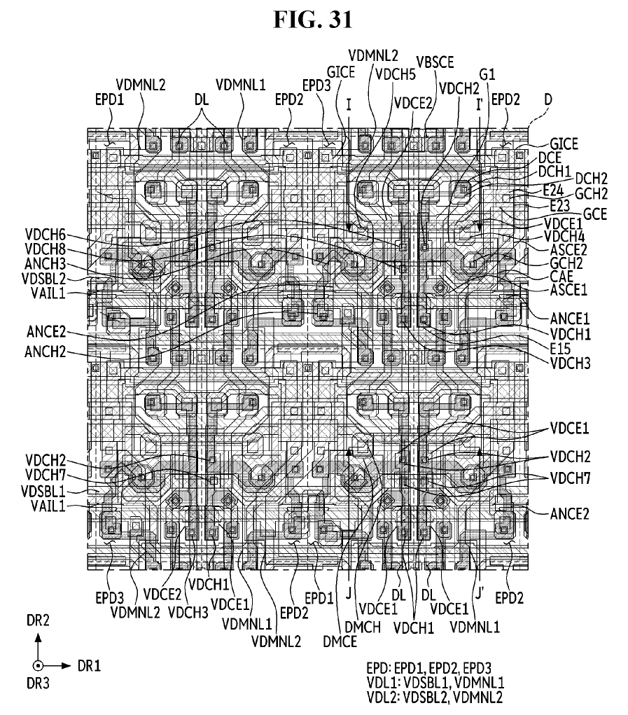

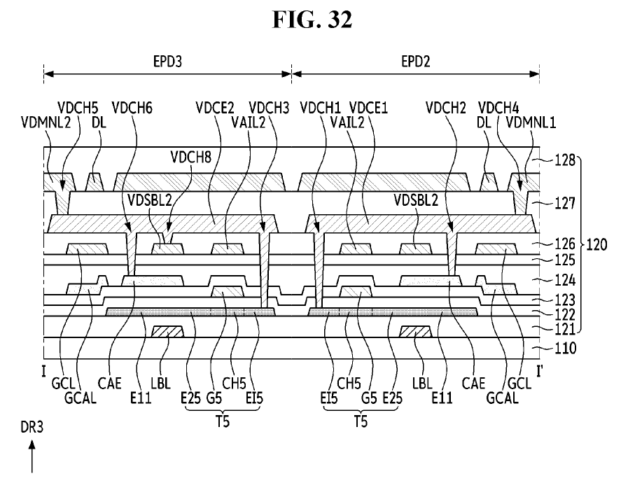

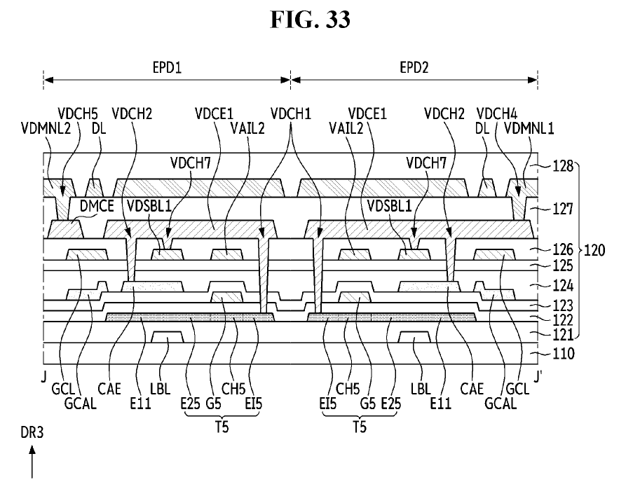

FIGS. 28, 29, 30, and 31 are schematic views showing an embodiment of the circuit layer of part D of FIG. 5. FIG. 32 is a cross-sectional view taken along line I-I' of FIG. 31. FIG. 33 is a cross-sectional view taken along line J-J' of FIG. 31.

In an embodiment shown in FIGS. 28 to 31, the remainder of the circuit layer 120 except for the second gate conductive layer GCDL2 and the third gate conductive layer GCDL3, that is, the first semiconductor layer SEL1, the first gate conductive layer GCDL1, the second semiconductor layer SEL2, the first source-drain conductive layer SDCDL1, and the second source-drain conductive layer SDCDL2 are substantially the same as or similar to those in the embodiment shown in FIGS. 13, 15, 16, and 18, and thus redundant description is omitted below.

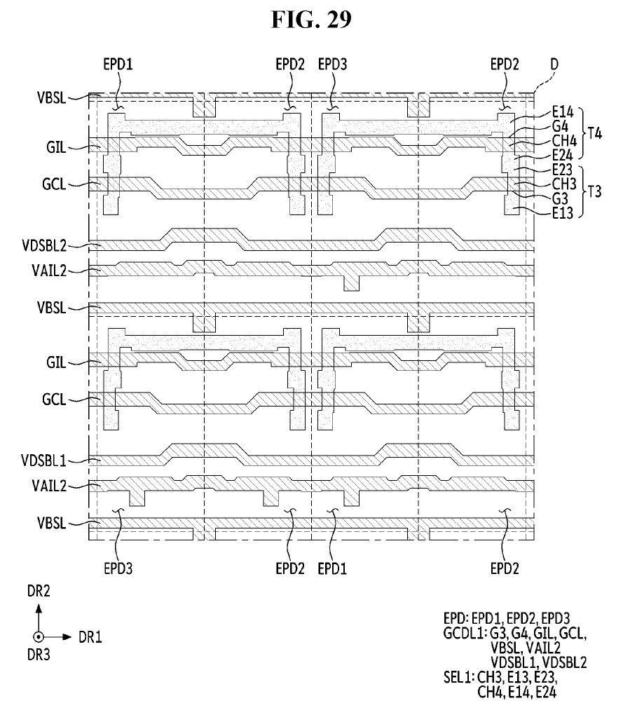

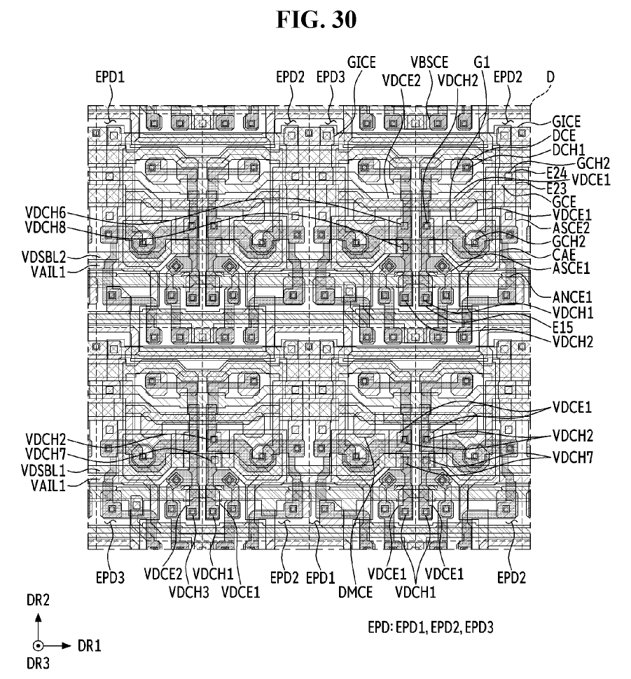

FIG. 28 illustrates an embodiment of the second gate conductive layer GCDL2 of the circuit layer of part D in FIG. 5 according to FIG. 27. FIG. 29 shows an embodiment of the second semiconductor layer SEL2 and the third gate conductive layer GCDL3 of the circuit layer of part D in FIG. 5 according to FIG. 27. FIG. 30 illustrates an embodiment of the first semiconductor layer SEL1, the first gate conductive layer GCDL1, the second gate conductive layer GCDL2, the second semiconductor layer SEL2, the third gate conductive layer GCDL3, and the first source-drain conductive layer SDCDL1 of the circuit layer of part D in FIG. 5 according to FIG. 27. FIG. 31 shows an embodiment of the first semiconductor layer SEL1, the first gate conductive layer GCDL1, the second gate conductive layer GCDL2, the second semiconductor layer SEL2, the third gate conductive layer GCDL3, the first source-drain conductive layer SDCDL1, and the second source-drain conductive layer SDCDL2 of the circuit layer of part D in FIG. 5 according to FIG. 27.

As shown in FIG. 28, in an embodiment, each of the light-emitting pixel drivers EPD may include the capacitor electrode CAE disposed in the second gate conductive layer GCDL2 in an island shape.

The capacitor electrodes CAE of two neighboring light-emitting pixel drivers EPD in the first direction DR1 may be symmetrical with respect to the boundary between the two neighboring light-emitting pixel drivers EPD.

As shown in FIG. 29, in an embodiment, the first power sub-line VDSBL1 and the second power sub-line VDSBL2 may be disposed in the third gate conductive layer GCDL3 and extend in the first direction DR1.

The first power sub-line VDSBL1 and the second power sub-line VDSBL2 may be alternately arranged in the second direction DR2.

Accordingly, one of two light-emitting pixel drivers EPD next (adjacent) to each other in the second direction DR2 (e.g., the light-emitting pixel driver disposed in the second row of FIG. 29) may intersect the first power sub-line VDSBL1, and a remaining (the other) light-emitting pixel driver (e.g., the light-emitting pixel driver disposed in the first row of FIG. 29) may intersect the second power sub-line VDSBL2.

As shown in FIGS. 30, 32, and 33, the first power connection electrode VDCE1 may be electrically connected to the first electrode E15 of the fifth transistor T5 (refer to FIG. 27) of the first light-emitting pixel driver EPD1 and the first electrode E15 of the fifth transistor T5 (refer to FIG. 27) of the second light-emitting pixel driver EPD2 through the first power connection hole VDCH1.

In an embodiment, the first power connection electrode VDCE1 may be electrically connected to the capacitor electrode CAE of the first light-emitting pixel driver EPD1 and the capacitor electrode CAE of the second light-emitting pixel driver EPD2 through the second power connection hole VDCH2.

In an embodiment, the first power connection electrode VDCE1 may be electrically connected to the first power sub-line VDSBL1 through a seventh power connection hole VDCH7.

As illustrated in FIGS. 31 and 33, the first power main line VDMNL1 may be electrically connected to the first power connection electrode VDCE1 through the fourth power connection hole VDCH4.

Accordingly, the first electrode E15 of the fifth transistor T5 (refer to FIG. 27) and the capacitor electrode CAE of each of the first and second light-emitting pixel drivers EPD1 and EPD2 and the first power sub-line VDSBL1 may be electrically connected to the first power main line VDMNL1 through the first power connection electrode VDCE1.

As shown in FIGS. 30 and 32, the second power connection electrode VDCE2 may be electrically connected to the first electrode E15 of the fifth transistor T5 (refer to FIG. 27) of the third light-emitting pixel driver EPD3 through the third power connection hole VDCH3.

In an embodiment, the second power connection electrode VDCE2 may be electrically connected to the capacitor electrode CAE of the third light-emitting pixel driver EPD3 through the sixth power connection hole VDCH6.

In an embodiment, the second power connection electrode VDCE2 may be electrically connected to the second power sub-line VDSBL2 through an eighth power connection hole VDCH8.

As illustrated in FIGS. 31 and 33, the second power main line VDMNL2 may be electrically connected to the second power connection electrode VDCE2 through the fifth power connection hole VDCH5.

Accordingly, the first electrode E15 of the fifth transistor T5 (refer to FIG. 27) and the capacitor electrode CAE of the third light-emitting pixel driver EPD3, and the second power sub-line VDSBL2 may be electrically connected to the second power main line VDMNL2 through the second power connection electrode VDCE2.

The display device 100 of each embodiment as described above may be applied to various electronic devices 10.

The electronic device 10 in an embodiment may include the display device 100 described above.

Additionally, the electronic device 10 in an embodiment may further include a module or device having other additional functions in addition to the display device 100.

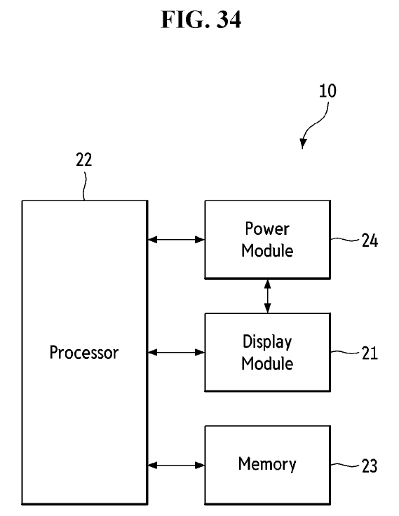

FIG. 34 is a block diagram of an embodiment of an electronic device.

Referring to FIG. 34, the electronic device 10 in an embodiment may include a display module 21, a processor 22, a memory 23, and a power module 24.

The display module 21 may include the display device 100 that displays an image.

The processor 22 may include at least one of a central processing unit (“CPU”), an application processor (“AP”), a graphic processing unit (“GPU”), a communication processor (“CP”), an image signal processor (“ISP”), or a controller.

The memory 23 may store data information desired for the operation of the processor 22 or the display module 21. When the processor 22 executes an application stored in the memory 23, an image data signal and/or an input control signal is transmitted to the display module 21, and the display module 21 may process the received signal and output image information through a display screen.

The power module 24 may include a power supply module, such as a power adapter or a battery device, and a power conversion module that converts the power supplied by the power supply module to generate the power desired for the operation of the electronic device 10.

At least one of the components of the electronic device 10 described above may be included in the display device in the embodiments described above. Further, some of individual modules functionally included in one module may be included in the display device and some others may be provided separately from the display device. In an embodiment, the display device may include the display module 21, and the processor 22, the memory 23, and the power module 24 may be provided in the form of other devices in the electronic device 10 other than the display device, for example.

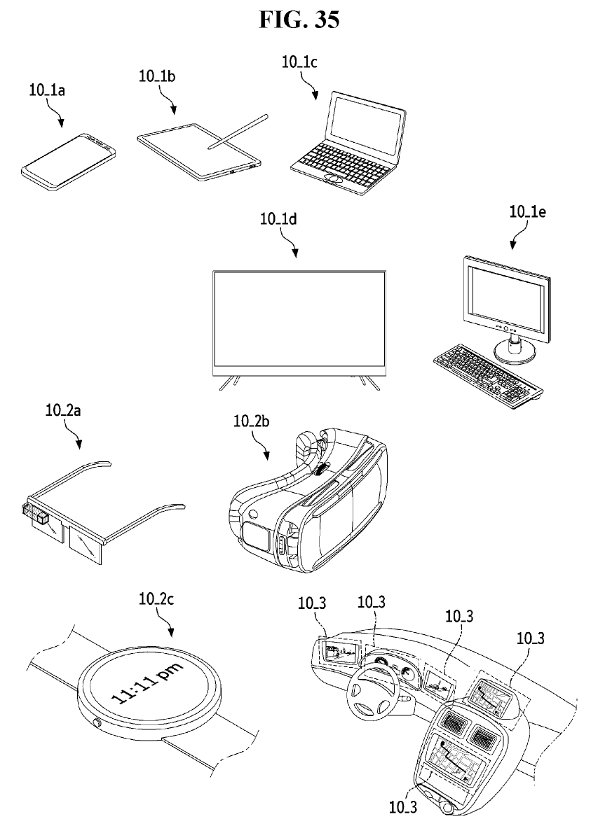

FIG. 35 is schematic views of an embodiment of electronic devices.

Referring to FIG. 35, the electronic devices 10 in the embodiments may include not only an image display electronic device such as a smartphone 10_1a, a tablet personal computer (“PC”) 10_1b, a laptop 10_1c, a television (“TV”) 10_1d, and a desk monitor 10_1e, but also a wearable electronic device such as smart glasses 10_2a, a head disposed (e.g., mounted) display 10_2b, and a smart watch 10_2c, and a vehicle electronic device 10_3 such as a dashboard of a vehicle, a center fascia, a center information display (“CID”) of the dashboard, and a room mirror display.

However, the effects of the disclosure are not restricted to the one set forth herein. The above and other effects of the disclosure will become more apparent to one of daily skill in the art to which the disclosure pertains by referencing the claims.

What is claimed is:

1. A display device comprising:
a substrate comprising a display area in which emission areas are arranged;
an element layer disposed on the substrate, the element layer comprising:
light-emitting elements arranged in each of the emission areas, and
a circuit layer disposed between the substrate and the element layer, the circuit layer comprising:
light-emitting pixel drivers which are arranged in a first direction and a second direction intersecting the first direction and transmit a driving current to the light-emitting elements;
a first power main line which extends in the second direction and transmits a first power to at least some of the light-emitting pixel drivers; and
a second power main line which extends in the second direction and transmits a second power different from the first power to some others of the light-emitting pixel drivers.

2. The display device of claim 1, wherein the emission areas comprise a first emission area, a second emission area, and a third emission area which emit light of different wavelength bands, and
the light-emitting pixel drivers comprise:
a first light-emitting pixel driver electrically connected to a light-emitting element of the first emission area among the light-emitting elements;
a second light-emitting pixel driver electrically connected to a light-emitting element of the second emission area among the light-emitting elements; and
a third light-emitting pixel driver electrically connected to a light-emitting element of the third emission area among the light-emitting elements,
the first power main line is electrically connected to the first light-emitting pixel driver and the second light-emitting pixel driver, and
the second power main line is electrically connected to the third light-emitting pixel driver.

3. The display device of claim 2, wherein each of the light-emitting pixel drivers comprises:
a first transistor which generates the driving current;
a first capacitor electrically connected to a gate electrode of the first transistor;
a second transistor electrically connected between a data line which transmits a data signal and a first electrode of the first transistor;
a third transistor electrically connected between the gate electrode of the first transistor and a second electrode of the first transistor;
a fourth transistor electrically connected between a gate initialization voltage line which transmits a gate initialization voltage and the gate electrode of the first transistor;
a fifth transistor electrically connected to the first electrode of the first transistor; and
a sixth transistor electrically connected between the second electrode of the first transistor and an output node,
wherein the output node is electrically connected to one of the light-emitting elements,
the fifth transistor of the first light-emitting pixel driver and the fifth transistor of the second light-emitting pixel driver are electrically connected to the first power main line, and
the fifth transistor of the third light-emitting pixel driver is electrically connected to the second power main line.

4. The display device of claim 3, wherein the circuit layer further comprises:
a first semiconductor layer disposed on the substrate;
a first inter-insulating layer disposed on the first semiconductor layer;
a second semiconductor layer disposed on the first inter-insulating layer;
a second inter-insulating layer disposed on the second semiconductor layer;
a first source-drain conductive layer disposed on the second inter-insulating layer;
a first planarization layer covering the first source-drain conductive layer;
a second source-drain conductive layer disposed on the first planarization layer; and
a second planarization layer covering the second source-drain conductive layer,
wherein a channel portion, a first electrode and a second electrode of each of the first transistor and the fifth transistor are arranged in the first semiconductor layer, and
a channel portion, a first electrode and a second electrode of each of the third transistor and the fourth transistor are arranged in the second semiconductor layer.

5. The display device of claim 4, wherein
each of the first power main line and the second power main line is disposed in the second source-drain conductive layer,
each of the first light-emitting pixel driver and the second light-emitting pixel driver comprises
a first power connection electrode disposed in the first source-drain conductive layer and electrically connected to the first power main line,
the first electrode of the fifth transistor of each of the first light-emitting pixel driver and the second light-emitting pixel driver is electrically connected to the first power main line through the first power connection electrode,
the third light-emitting pixel driver comprises a second power connection electrode disposed in the first source-drain conductive layer and electrically connected to the second power main line, and
the first electrode of the fifth transistor of the third light-emitting pixel driver is electrically connected to the second power main line through the second power connection electrode.

6. The display device of claim 5, wherein
the first light-emitting pixel driver and the third light-emitting pixel driver are arranged alternately in the second direction,
the second light-emitting pixel driver is provided in plural in a manner that second light-emitting pixel drivers are arranged side by side in the second direction,
the second light-emitting pixel driver is disposed between the first light-emitting pixel driver and the third light-emitting pixel driver in the first direction,
the first power main line intersects the second light-emitting pixel driver,
the second power main line intersects the first light-emitting pixel driver and the third light-emitting pixel driver,
a first power connection electrode of the first light-emitting pixel driver and a first power connection electrode of the second light-emitting pixel driver which are next to each other in the first direction are connected to each other, and
the first power connection electrode of the first light-emitting pixel driver is electrically connected to the first power main line through the first power connection electrode of the second light-emitting pixel driver next to the first light-emitting pixel driver.

7. The display device of claim 6, wherein the circuit layer further comprises a first power sub-line extending in the first direction and electrically connected to the first power main line,
each of the light-emitting pixel drivers intersects the first power sub-line, and
the first capacitor of each of the light-emitting pixel drivers is electrically connected to the first power sub-line.

8. The display device of claim 7, wherein the circuit layer further comprises:
a first gate insulating layer covering the first semiconductor layer;
a first gate conductive layer disposed on the first gate insulating layer;
a second gate insulating layer covering the first gate conductive layer; and
a second gate conductive layer disposed between the second gate insulating layer and the first inter-insulating layer,
wherein the gate electrode of the first transistor is disposed in the first gate conductive layer,
the first power sub-line is disposed in the second gate conductive layer and electrically connected to the first power main line through the first power connection electrode,
each of the light-emitting pixel drivers further comprises a capacitor electrode disposed in the second gate conductive layer and overlapping the gate electrode of the first transistor in a third direction perpendicular to the first and second directions,
the capacitor electrode is a portion of the first power sub-line which overlaps the gate electrode of the first transistor, and
the first capacitor is formed in a region where the gate electrode of the first transistor and the capacitor electrode overlap each other in the third direction.

9. The display device of claim 5, wherein the circuit layer further comprises:
a first power sub-line extending in the first direction and electrically connected to the first power main line; and
a second power sub-line extending in the first direction and electrically connected to the second power main line,
wherein between two light-emitting pixel drivers next to each other in the second direction, one light-emitting pixel driver intersects the first power sub-line, and a remaining light-emitting pixel driver intersects the second power sub-line.

10. The display device of claim 9, wherein the first capacitor of the one light-emitting pixel driver is electrically connected to the first power sub-line, and
the first capacitor of the remaining light-emitting pixel driver is electrically connected to the second power sub-line.

11. The display device of claim 10, wherein the circuit layer further comprises:
a first gate insulating layer covering the first semiconductor layer;
a first gate conductive layer disposed on the first gate insulating layer;
a second gate insulating layer covering the first gate conductive layer; and
a second gate conductive layer disposed between the second gate insulating layer and the first inter-insulating layer,
wherein the gate electrode of the first transistor is disposed in the first gate conductive layer,
the first power sub-line and the second power sub-line are disposed in the second gate conductive layer,
each of the light-emitting pixel drivers further comprises a capacitor electrode disposed in the second gate conductive layer and overlapping the gate electrode of the first transistor in a third direction perpendicular to the first and second directions,
the first capacitor is formed in a region where the gate electrode of the first transistor and the capacitor electrode overlap each other,
the capacitor electrode of the one light-emitting pixel driver is a part of the first power sub-line, and
the capacitor electrode of the remaining light-emitting pixel driver is a part of the second power sub-line.

12. The display device of claim 9, wherein
the first capacitor of the first light-emitting pixel driver and the first capacitor of the second light-emitting pixel driver are electrically connected to the first power main line, and
the first capacitor of the third light-emitting pixel driver is electrically connected to the second power main line.

13. The display device of claim 12, wherein the circuit layer further comprises:
a first gate insulating layer covering the first semiconductor layer;
a first gate conductive layer disposed on the first gate insulating layer;
a second gate insulating layer covering the first gate conductive layer;
a second gate conductive layer disposed between the second gate insulating layer and the first inter-insulating layer,
a third gate insulating layer covering the second semiconductor layer; and
a third gate conductive layer disposed between the third gate insulating layer and the second inter-insulating layer,
wherein the gate electrode of the first transistor is disposed in the first gate conductive layer,
each of the light-emitting pixel drivers further comprises a capacitor electrode disposed in an island shape in the second gate conductive layer and overlapping the gate electrode of the first transistor in a third direction perpendicular to the first and second directions,
the first capacitor is formed in a region where the gate electrode of the first transistor and the capacitor electrode overlap each other,
the first power sub-line and the second power sub-line are disposed in the third gate conductive layer,
the first power sub-line, the capacitor electrode of the first light-emitting pixel driver, and the capacitor electrode of the second light-emitting pixel driver are electrically connected to the first power main line through the first power connection electrode, and
the second power sub-line and the capacitor electrode of the third light-emitting pixel driver are electrically connected to the second power main line through the second power connection electrode.

14. The display device of claim 2, wherein
the first emission area emits light of a first wavelength band,
the second emission area emits light of a second wavelength band lower than the first wavelength band,
the third emission area emits light of a third wavelength band lower than the second wavelength band,
each of the light-emitting elements comprises an anode electrode and a cathode electrode opposing each other in a third direction perpendicular to the first and second directions, and an organic layer disposed between the anode electrode and the cathode electrode,
each of the organic layer of the light-emitting element of the first emission area and the organic layer of the light-emitting element of the second emission area comprises one light-emitting stack,
the organic layer of the light-emitting element of the third emission area comprises two or more light-emitting stacks, and at least one carrier generation layer disposed between the two or more light-emitting stacks, and
each of the one light-emitting stack and the two or more light-emitting stacks comprises a light-emitting layer in which an electron-hole pair is converted into light.

15. An electronic device comprising:
a display device displaying an image, the display device comprising:
a substrate comprising:
a display area in which emission areas are arranged, the emission areas comprising:
a first emission area;
a second emission area; and
a third emission area which emit light of different wavelength bands;
an element layer disposed on the substrate, the element layer comprising:
light-emitting elements arranged in each of the emission areas;
a circuit layer disposed between the substrate and the element layer, the circuit layer comprising:
light-emitting pixel drivers which are arranged in a first direction and a second direction intersecting the first direction and transmit a driving current to the light-emitting elements, the light-emitting pixel drivers comprising:
a first light-emitting pixel driver electrically connected to the light-emitting element of the first emission area;
a second light-emitting pixel driver electrically connected to the light-emitting element of the second emission area; and
a third light-emitting pixel driver electrically connected to the light-emitting element of the third emission area;
a first power main line extending in the second direction and transmitting a first power to at least some of the light-emitting pixel drivers; and
a second power main line extending in the second direction and transmitting a second power different from the first power to some others of the light-emitting pixel drivers;
a memory storing an application;
a processor executing the application and transmitting an image data signal and an input control signal to the display device; and
a power module transmitting a power to the display device,
wherein the first power main line is electrically connected to the first light-emitting pixel driver and the second light-emitting pixel driver, and
the second power main line is electrically connected to the third light-emitting pixel driver.

16. The electronic device of claim 15, wherein each of the light-emitting pixel drivers comprises:
a first transistor which generates the driving current;
a first capacitor electrically connected to a gate electrode of the first transistor;
a second transistor electrically connected between a data line which transmits a data signal and a first electrode of the first transistor;
a third transistor electrically connected between the gate electrode of the first transistor and a second electrode of the first transistor;
a fourth transistor electrically connected between a gate initialization voltage line which transmits a gate initialization voltage and the gate electrode of the first transistor;
a fifth transistor electrically connected to the first electrode of the first transistor; and
a sixth transistor electrically connected between the second electrode of the first transistor and an output node,
wherein the output node is electrically connected to one of the light-emitting elements, and
the circuit layer further comprises:
a first semiconductor layer disposed on the substrate;
a first inter-insulating layer disposed on the first semiconductor layer;
a second semiconductor layer disposed on the first inter-insulating layer;
a second inter-insulating layer disposed on the second semiconductor layer;
a first source-drain conductive layer disposed on the second inter-insulating layer;
a first planarization layer covering the first source-drain conductive layer;
a second source-drain conductive layer disposed on the first planarization layer; and
a second planarization layer covering the second source-drain conductive layer,
wherein a channel portion, a first electrode and a second electrode of each of the first transistor and the fifth transistor are arranged in the first semiconductor layer,
the first power main line and the second power main line are disposed in the second source-drain conductive layer,
each of the first light-emitting pixel driver and the second light-emitting pixel driver comprises a first power connection electrode disposed in the first source-drain conductive layer and electrically connected to the first power main line,
the first electrode of the fifth transistor of each of the first light-emitting pixel driver and the second light-emitting pixel driver is electrically connected to the first power main line through the first power connection electrode,
the third light-emitting pixel driver comprises a second power connection electrode disposed in the first source-drain conductive layer and electrically connected to the second power main line, and
the first electrode of the fifth transistor of the third light-emitting pixel driver is electrically connected to the second power main line through the second power connection electrode.

17. The electronic device of claim 16, wherein the circuit layer further comprises:
a first gate insulating layer covering the first semiconductor layer;
a first gate conductive layer disposed on the first gate insulating layer;
a second gate insulating layer covering the first gate conductive layer;
a second gate conductive layer disposed between the second gate insulating layer and the first inter-insulating layer; and
a first power sub-line extending in the first direction, disposed in the second gate conductive layer, and electrically connected to the first power main line through the first power connection electrode,
wherein each of the light-emitting pixel drivers intersects the first power sub-line, and
the first capacitor of each of the light-emitting pixel drivers is electrically connected to the first power sub-line.

18. The electronic device of claim 16, wherein the circuit layer further comprises:
a first gate insulating layer covering the first semiconductor layer;
a first gate conductive layer disposed on the first gate insulating layer;
a second gate insulating layer covering the first gate conductive layer;
a second gate conductive layer disposed between the second gate insulating layer and the first inter-insulating layer;
a first power sub-line extending in the first direction, disposed in the second gate conductive layer, and electrically connected to the first power main line through the first power connection electrode; and
a second power sub-line extending in the first direction, disposed in the second gate conductive layer, and electrically connected to the second power main line through the second power connection electrode,
wherein between two light-emitting pixel drivers next to each other in the second direction, one light-emitting pixel driver intersects the first power sub-line, and a remaining light-emitting pixel driver intersects the second power sub-line,
the gate electrode of the first transistor is disposed in the first gate conductive layer,
each of the light-emitting pixel drivers further comprises a capacitor electrode disposed in the second gate conductive layer, and overlapping the gate electrode of the first transistor in a third direction perpendicular to the first and second directions,
the first capacitor is formed in a region where the gate electrode of the first transistor and the capacitor electrode overlap each other,
the capacitor electrode of the one light-emitting pixel driver is a part of the first power sub-line, and
the capacitor electrode of the remaining light-emitting pixel driver is a part of the second power sub-line.

19. The electronic device of claim 16, wherein the circuit layer further comprises:
a first power sub-line extending in the first direction and electrically connected to the first power main line; and
a second power sub-line extending in the first direction and electrically connected to the second power main line,
wherein between two light-emitting pixel drivers next to each other in the second direction, one light-emitting pixel driver intersects the first power sub-line, and a remaining light-emitting pixel driver intersects the second power sub-line,
the first capacitor of the first light-emitting pixel driver and the first capacitor of the second light-emitting pixel driver are electrically connected to the first power main line through the first power connection electrode, and
the first capacitor of the third light-emitting pixel driver is electrically connected to the second power main line through the second power connection electrode.

20. The electronic device of claim 19, wherein the circuit layer further comprises:
a first gate insulating layer covering the first semiconductor layer;
a first gate conductive layer disposed on the first gate insulating layer;
a second gate insulating layer covering the first gate conductive layer;
a second gate conductive layer disposed between the second gate insulating layer and the first inter-insulating layer,
a third gate insulating layer covering the second semiconductor layer; and
a third gate conductive layer disposed between the third gate insulating layer and the second inter-insulating layer,
wherein the gate electrode of the first transistor is disposed in the first gate conductive layer,
each of the light-emitting pixel drivers further comprises a capacitor electrode disposed in an island shape in the second gate conductive layer and overlapping the gate electrode of the first transistor in a third direction perpendicular to the first and second directions,
the first capacitor is formed in a region where the gate electrode of the first transistor and the capacitor electrode overlap each other,
the first power sub-line and the second power sub-line are disposed in the third gate conductive layer,
the first power sub-line, the capacitor electrode of the first light-emitting pixel driver, and the capacitor electrode of the second light-emitting pixel driver are electrically connected to the first power main line through the first power connection electrode, and
the second power sub-line and the capacitor electrode of the third light-emitting pixel driver are electrically connected to the second power main line through the second power connection electrode.
